(19) United States
(12) Patent Application Publication
(10) Pub. No.: US 2016/0141490 A1
(43) Pub. Date: May 19, 2016

(54) MAGNETIC MEMORY DEVICES AND METHODS OF FORMING THE SAME

(71) Applicants: Hyunsung JUNG, Suwon-si (KR); Daeeun JEONG, Yongin-si (KR)

(72) Inventors: Hyunsung JUNG, Suwon-si (KR); Daeeun JEONG, Yongin-si (KR)

(21) Appl. No.: 14/796,022

(22) Filed: Jul. 10, 2015

(30) Foreign Application Priority Data
Nov. 14, 2014 (KR) 10-2014-0159091

(51) Int. Cl. H01L 43/10; H01L 43/02

(52) U.S. Cl. CPC H01L 43/10; H01L 43/02

(57) ABSTRACT

Provided are a magnetic memory device and a method of forming the same. The magnetic memory device includes a contact plug, which includes a first crystalline region and an amorphous region located on the first crystalline region, and a magnetic tunnel junction pattern located on the amorphous region of the contact plug.

### CROSS-REFERENCE TO RELATED APPLICATION

This application claims priority under 35 U.S.C. §119 to Korean Patent Application No. 10-2014-0159091 filed on Nov. 14, 2014, the disclosure of which is hereby incorporated by reference in its entirety.

### BACKGROUND

1. Field

Embodiments relate to a magnetic memory device including a magnetic tunnel junction pattern and a method of forming the same.

2. Description of Related Art

A magnetic memory device includes a magnetic tunnel junction pattern. The magnetic tunnel junction pattern may include components stacked in a vertical direction. For example, the magnetic tunnel junction pattern may include a lower magnetic pattern, an upper magnetic pattern, and a tunnel barrier pattern between the lower magnetic pattern and the upper magnetic pattern. The magnetic tunnel junction pattern may be located on a contact plug. In the case of a magnetic memory device, various researches have been progressed for preventing a change of electromagnetic characteristics of a magnetic tunnel junction pattern caused by a contact plug.

### SUMMARY

Embodiments provide a magnetic memory device capable of preventing a change of electromagnetic characteristics of a magnetic tunnel junction pattern caused by a contact plug and a method of forming the same.

Other embodiments provide a magnetic memory device capable of preventing an influence of a contact plug on a magnetic tunnel junction pattern without increasing an overall height and a method of forming the same.

Embodiments are not limited to the above-mentioned embodiments. Other embodiments which are not mentioned herein may be clearly understood by those of ordinary skills in the art based on the following descriptions.

According to an aspect of embodiments, a magnetic memory device includes a contact plug, which includes a first crystalline region and an amorphous region located on the first crystalline region, and a magnetic tunnel junction pattern located on the amorphous region of the contact plug.

The amorphous region may include the same conductive material as the first crystalline region.

An amount of the conductive material in the amorphous region may be smaller than an amount of the conductive material in the first crystalline region.

A vertical thickness of the amorphous region may be smaller than a vertical thickness of the first crystalline region.

The magnetic tunnel junction pattern may include magnetic patterns and a tunnel barrier pattern disposed between the magnetic patterns, and a crystallization temperature of the magnetic patterns may be lower than a crystallization temperature of the amorphous region of the contact plug.

The magnetic memory device may further include a lower interlayer insulating layer surrounding the contact plug, an upper surface of the amorphous region of the contact plug may be coplanar with an upper surface of the lower interlayer insulating layer.

In accordance with another aspect of the embodiments, a magnetic memory device includes a contact plug, which includes a first crystalline region and a second crystalline region including the same conductive material as the first crystalline region, and a magnetic tunnel junction pattern located on the second crystalline region of the contact plug. The second crystalline region has a different crystalline structure from the first crystalline region.

The second crystalline region may have the same composition ratio as the first crystalline region.

The contact plug may further include an amorphous region located between the first crystalline region and the second crystalline region.

The amorphous region may include a same conductive material as the second crystalline region.

The contact plug may further include a third crystalline region having a different conductive material from the first crystalline region. The first crystalline region may be located between the second crystalline region and the third crystalline region.

The first crystalline region may have a same crystalline structure as the third crystalline region.

A vertical thickness of the third crystalline region may be greater than a vertical thickness of the first crystalline region.

A horizontal width of an upper surface of the second crystalline region may be different from a horizontal width of a lower surface of the magnetic tunnel junction pattern.

The magnetic tunnel junction pattern may include a seed pattern in direct contact with the second crystalline region of the contact plug, and the seed pattern may have a same crystalline structure as the second crystalline region of the contact plug.

In accordance with yet another aspect of the embodiments, a magnetic memory device includes a lower interlayer insulating layer including a via hole, a contact plug located in the via hole of the lower interlayer insulating layer, and a magnetic tunnel junction pattern located on the contact plug. The contact plug includes an amorphous region disposed near the magnetic tunnel junction pattern.

The amorphous region of the contact plug may directly contact the magnetic tunnel junction pattern.

The magnetic memory device may further include a core pattern disposed on the contact plug, an upper surface of the core pattern may be coplanar with an upper surface of the contact plug.

A level of a lower surface of the core pattern may be lower than a lowest level of the amorphous region of the contact plug.

The core pattern may include silicon oxide.

### BRIEF DESCRIPTION OF THE DRAWINGS

The foregoing and other features and advantages will be apparent from the more particular description of preferred embodiments, as illustrated in the accompanying drawings in which like reference characters refer to the same parts throughout the different views. The drawings are not necessarily to scale, emphasis instead being placed upon illustrating the principles of the embodiments. In the drawings:

FIG. 1 is a view schematically illustrating a magnetic memory device according to an embodiment;

FIG. 2 is a cross-sectional view schematically illustrating a memory cell of the magnetic memory device in FIG. 1;

FIG. 3 is a cross-sectional view schematically illustrating a magnetic memory device according to another embodiment;

FIG. 4 is a cross-sectional view schematically illustrating a magnetic memory device according to still another embodiment;

FIG. 5 is a cross-sectional view schematically illustrating a magnetic memory device according to yet another embodiment;

FIG. 6 is a cross-sectional view schematically illustrating a magnetic memory device according to yet another embodiment;

FIG. 7 is a cross-sectional view schematically illustrating a magnetic memory device according to yet another embodiment;

FIG. 8 is a cross-sectional view schematically illustrating a magnetic memory device according to yet another embodiment;

FIG. 9 is a cross-sectional view schematically illustrating a magnetic memory device according to yet another embodiment;

FIGS. 10A to 10J are cross-sectional views illustrating stages in a method of forming a magnetic memory device according to an embodiment;

FIGS. 11A to 11C are cross-sectional views illustrating stages in a method of forming a magnetic memory device according to another embodiment;

FIGS. 12A and 12B are cross-sectional views illustrating stages in a method of forming a magnetic memory device according to still another embodiment;

FIGS. 13A to 13D are cross-sectional views illustrating stages in a method of forming a magnetic memory device according to yet another embodiment;

FIGS. 14A to 14D are cross-sectional views illustrating stages in a method of forming a magnetic memory device according to yet another embodiment;

FIG. 15 is a view schematically illustrating a memory module having a magnetic memory device according to an embodiment;

FIG. 16 is a view schematically illustrating a mobile system having a magnetic memory device according to an embodiment;

FIG. 17 is a view schematically illustrating a mobile device having a magnetic memory device according to an embodiment; and

FIG. 18 is a view schematically illustrating an electronic system having a magnetic memory device according to an embodiment.

### DETAILED DESCRIPTION OF THE EMBODIMENTS

Particular structural and functional descriptions regarding embodiments set forth herein are simply provided to explain these embodiments. These embodiments are provided so that this disclosure is thorough and complete and fully conveys the embodiments to those skilled in the art. Thus, exemplary implementations may be accomplished in other various embodiments and should not be construed as limited to those set forth herein.

Like numerals refer to like elements throughout the specification. In the drawings, the lengths and thicknesses of layers and regions may be exaggerated for clarity. In addition, it will be understood that when a first element is referred to as being “on” a second element, the first element may be directly on the second element, or a third element may be interposed between the first element and the second element.

It will be understood that the terms “first,” “second,” etc. are used herein to describe various elements and used for the purpose of distinguishing one element from another element. Thus, without deviating from the scope of the embodiments, a first element and a second element may be arbitrarily named for the sake of convenience for those skilled in the art.

The terminology used herein is only intended to describe specific embodiments and is not intended to limit. For example, the singular forms “a,” “an,” and “the” are intended to include the plural forms as well, unless the context clearly indicates otherwise. Also, it will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of skill in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

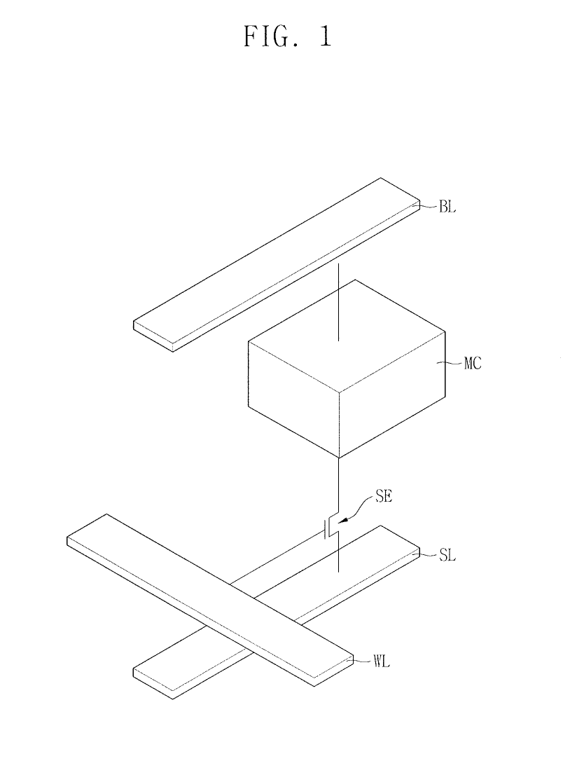

FIG. 1 is a view schematically illustrating a magnetic memory device according to an embodiment.

Referring to FIG. 1, the magnetic memory device according to the embodiment may include a bit line BL, a word line WL, a source line SL, a switching element SE, and a memory cell MC.

The word line WL may cross the bit line BL. The source line SL may apply a common voltage. The source line SL may cross the word line WL. For example, the source line SL may be parallel with the bit line BL.

The switching element SE may be located between the source line SL and the memory cell MC. The switching element SE may be controlled by the word line WL. For example, the switching element SE may include a transistor having a gate connecting the word line WL.

The memory cell MC may be located between the switching element SE and the bit line BL. A resistance of the memory cell MC may be changed with respect to signals transmitted by the word line WL and the bit line BL.

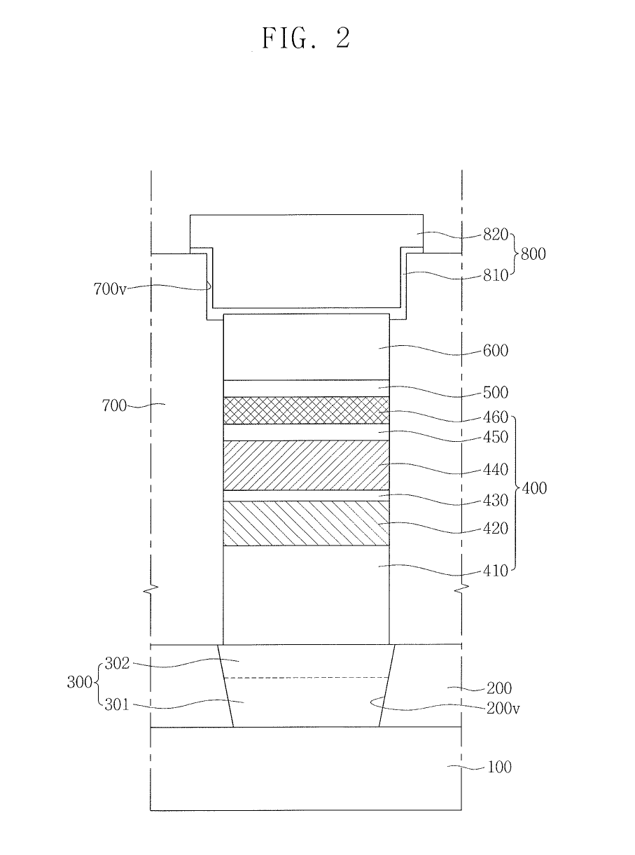

FIG. 2 is a cross-sectional view schematically illustrating a memory cell MC of a magnetic memory device according to an embodiment.

Referring to FIG. 2, the memory cell MC of the magnetic memory device according to the embodiment may include a substrate 100, a lower interlayer insulating layer 200, a contact plug 300, a magnetic tunnel junction pattern 400, a capping pattern 500, a metal mask pattern 600, an upper interlayer insulating layer 700, and an upper electrode 800.

The substrate 100 may be a semiconductor substrate. The lower interlayer insulating layer 200 may be located on the substrate 100. The lower interlayer insulating layer 200 may include an insulating material. For example, the lower interlayer insulating layer 200 may include silicon oxide or silicon nitride. The lower interlayer insulating layer 200 may include a lower via hole 200v.

The contact plug 300 may be electrically connected to the switching element SE illustrated in FIG. 1. The contact plug 300 may be located in the lower via hole 200v of the lower interlayer insulating layer 200. The contact plug 300 may include a lower crystalline region 301 and an amorphous region 302.

The lower crystalline region 301 may be located close to the substrate 100. The lower crystalline region 301 may include a conductive material. For example, the lower crystalline region 301 may include a metal such as Cu, W, or Ti. The lower crystalline region 301 may be a crystalline state.

The amorphous region 302 may be located on the lower crystalline region 301. The amorphous region 302 may directly contact the lower crystalline region 301. An upper surface of the amorphous region 302 may be coplanar with an upper surface of the lower interlayer insulating layer 200.

The amorphous region 302 may include the same conductive material as the lower crystalline region 301. The amorphous region 302 may further include impurities. For example, the amorphous region 302 may include a metal such as Cu, W, or Ti and one among B, As, N, and P. For example, the amorphous region 302 may include a metal nitride such as WN or TiN. An amount of the conductive material in the amorphous region 302 may be smaller than an amount of the conductive material in the lower crystalline region 301.

The amorphous region 302 may be an amorphous state. A vertical thickness of the amorphous region 302 may be smaller than a vertical thickness of the lower crystalline region 301.

The magnetic tunnel junction pattern 400 may be located on the contact plug 300. A horizontal width of a lower surface of the magnetic tunnel junction pattern 400 may be smaller than a horizontal width of an upper surface of the contact plug 300.

The magnetic tunnel junction pattern 400 may include a synthetic anti-ferromagnetic (SAF) structure. For example, the magnetic tunnel junction pattern 400 may include a seed pattern 410, a lower pinned magnetic pattern 420, a spacer 430, an upper pinned magnetic pattern 440, a tunnel barrier pattern 450, and a free magnetic pattern 460.

The seed pattern 410 may be located close to the contact plug 300. The seed pattern 410 may directly contact the amorphous region 302 of the contact plug 300. For example, the seed pattern 410 may include Ru, Ta, or Ti.

In the memory cell MC of the magnetic memory device according to an embodiment, the magnetic tunnel junction pattern 400 may be located on the amorphous region 302 of the contact plug 300. Therefore, in the memory cell MC of the magnetic memory device according to the embodiment, a crystalline structure of the seed pattern 410 may not be influenced by the lower crystalline region 301 of the contact plug 300. That is, in the memory cell MC of the magnetic memory device according to the embodiment, the seed pattern 410 may have a crystalline structure based on a unique characteristic. For example, in the memory cell MC of the magnetic memory device according to the embodiment, the seed pattern 410 may have a different crystalline structure from the lower crystalline region 301 of the contact plug 300.

The lower pinned magnetic pattern 420 may be located on the seed pattern 410. The lower pinned magnetic pattern 420 may include a magnetic material. A magnetization direction of the lower pinned magnetic pattern 420 may be perpendicular to a surface of the substrate 100. The lower pinned magnetic pattern 420 may have a vertical magnetization characteristic. For example, the lower pinned magnetic pattern 420 may include Pt, Pd, Ru, or Ta and at least one among Co, Fe, and Ni.

The magnetization direction of the lower pinned magnetic pattern 420 may be fixed. The magnetization direction of the lower pinned magnetic pattern 420 may not be influenced by an external magnetic field. For example, the magnetization direction of the lower pinned magnetic pattern 420 may not be changed by a magnetic field formed between the contact plug 300 and the upper electrode 800.

A crystalline structure of the lower pinned magnetic pattern 420 may be influenced by the seed pattern 410. For example, the lower pinned magnetic pattern 420 may have the same crystalline structure as the seed pattern 410.

The spacer 430 may be located on the lower pinned magnetic pattern 420. The spacer 430 may include a non-magnetic material. For example, the spacer 430 may include Ru, Ir, Re, or Os.

The upper pinned magnetic pattern 440 may be located on the spacer 430. The upper pinned magnetic pattern 440 may include a magnetic material. The upper pinned magnetic pattern 440 may have a vertical magnetization characteristic. The upper pinned magnetic pattern 440 may further include an amorphized material. For example, the upper pinned magnetic pattern 440 may include at least one among Co, Fe, and Ni, one among Pt, Pd, Ru, and Ta, and one among B, P, As, and Bi.

A magnetization direction of the upper pinned magnetic pattern 440 may be fixed. For example, the magnetization direction of the upper pinned magnetic pattern 440 may not be changed by a magnetic field formed between the contact plug 300 and the upper electrode 800.

The tunnel barrier pattern 450 may be located on the upper pinned magnetic pattern 440. The tunnel barrier pattern 450 may include a non-magnetic material. For example, the tunnel barrier pattern 450 may include MgO.

The tunnel barrier pattern 450 may have an influence on a crystalline structure of the upper pinned magnetic pattern 440. For example, the upper pinned magnetic pattern 440 may have the same crystalline structure as the tunnel barrier pattern 450.

The free magnetic pattern 460 may be located on the tunnel barrier pattern 450. The free magnetic pattern 460 may have a vertical magnetization characteristic. The free magnetic pattern 460 may include a magnetic material and an amorphized material. For example, the free magnetic pattern 460 may include at least one among Co, Fe, and Ni, one among Pt, Pd, Ru, and Ta, and one among B, P, As, and Bi.

A magnetization direction of the free magnetic pattern 460 may be changed. The magnetization direction of the free magnetic pattern 460 may be influenced by an external magnetic field. For example, the magnetization direction of the free magnetic pattern 460 may be changed by a magnetic field formed between the contact plug 300 and the upper electrode 800.

A crystalline structure of the free magnetic pattern 460 may be influenced by the tunnel barrier pattern 450. For example, the free magnetic pattern 460 may have the same crystalline structure as the tunnel barrier pattern 450.

The capping pattern 500 may be located on the magnetic tunnel junction pattern 400. The capping pattern 500 may directly contact the free magnetic pattern 460. For example, the capping pattern 500 may include at least one among Cu, Ta, Al, Au, Ti, TiN, and TaN. For example, the capping pattern 500 may be a multi-layer structure.

The metal mask pattern 600 may be located on the capping pattern 500. The metal mask pattern 600 may include a conductive material. For example, the metal mask pattern 600 may include a metal and a metal nitride.

The upper interlayer insulating layer 700 may be located on the lower interlayer insulating layer 200. The magnetic tunnel junction pattern 400, the capping pattern 500, and the metal mask pattern 600 may be surrounded by the upper interlayer insulating layer 700. A level of an upper surface of the upper interlayer insulating layer 700 may be higher than a level of an upper surface of the metal mask pattern 600.

The upper interlayer insulating layer 700 may include an insulating material. For example, the upper interlayer insulating layer 700 may include silicon oxide or silicon nitride. The upper interlayer insulating layer 700 may include the same insulating material as the lower interlayer insulating layer 200.

The upper interlayer insulating layer 700 may include an upper via hole 700v. The upper via hole 700v may be located on the metal mask pattern 600. A level of a bottom surface of the upper via hole 700v may be lower than a level of an upper surface of the metal mask pattern 600. A horizontal width of a bottom surface of the upper via hole 700v may be greater than a horizontal width of an upper surface of the metal mask pattern 600.

The upper electrode 800 may be electrically connected to the bit line BL illustrated in FIG. 1. The upper electrode 800 may be located in the upper via hole 700v of the upper interlayer insulating layer 700. The upper electrode 800 may include an upper barrier pattern 810 and an upper conductive pattern 820.

The upper barrier pattern 810 may be located on a surface of the upper interlayer insulating layer 700. The upper conductive pattern 820 may be located on the upper barrier pattern 810. A level of an upper surface of the upper conductive pattern 820 may be higher than a level of the upper surface of the upper interlayer insulating layer 700. A horizontal width of the upper conductive pattern 820 may be greater than a horizontal width of the upper via hole 700v. The upper barrier pattern 810 may be located between the upper interlayer insulating layer 700 and the upper conductive pattern 820.

The upper barrier pattern 810 and the upper conductive pattern 820 may include a conductive material. For example, the upper barrier pattern 810 may include a metal nitride, and the upper conductive pattern 820 may include a metal.

In the magnetic memory device according to an embodiment, the contact plug 300 may include the amorphous region 302 which directly contacts the magnetic tunnel junction pattern 400. That is, in the magnetic memory device according to the embodiment, the amorphous region 302 of the contact plug 300 may prevent an influence of the lower crystalline region 301 of the contact plug 300 on the magnetic tunnel junction pattern 400. Thus, in the magnetic memory device according to the embodiment, a change of electromagnetic characteristics of a magnetic tunnel junction pattern due to the influence of a contact plug may be prevented without a change of an overall height.

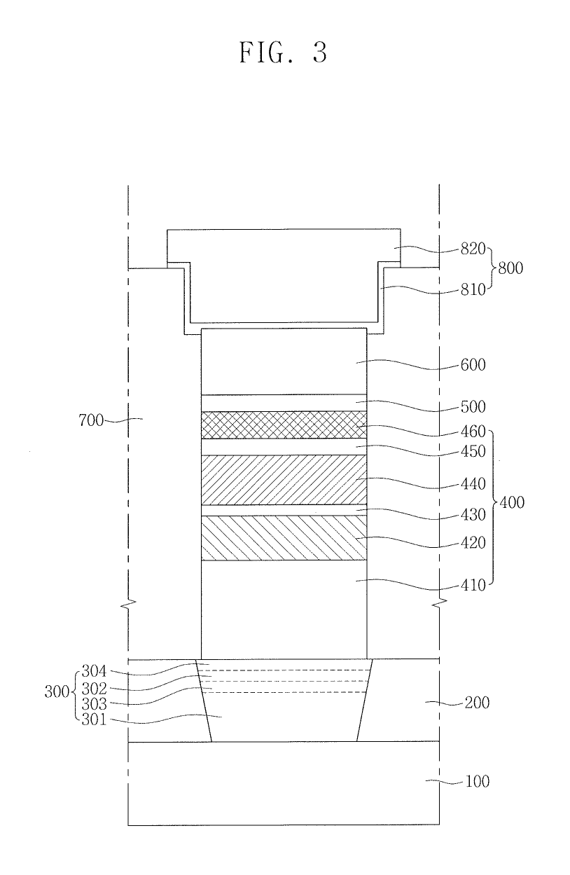

FIG. 3 is a cross-sectional view schematically illustrating a magnetic memory device according to an embodiment.

Referring to FIG. 3, the magnetic memory device according to the embodiment may include a substrate 100, a lower interlayer insulating layer 200, a contact plug 300, a magnetic tunnel junction pattern 400, a capping pattern 500, a metal mask pattern 600, an upper interlayer insulating layer 700, and an upper electrode 800.

The magnetic tunnel junction pattern 400 may include a seed pattern 410, a lower pinned magnetic pattern 420, a spacer 430, an upper pinned magnetic pattern 440, a tunnel barrier pattern 450, and a free magnetic pattern 460. The upper electrode 800 may include an upper barrier pattern 810 and an upper conductive pattern 820.

The contact plug 300 may include a lower crystalline region 301, an amorphous region 302, a middle crystalline region 303, and an upper crystalline region 304.

The lower crystalline region 301 may be disposed near the substrate 100. The lower crystalline region 301 may be a crystalline state. The amorphous region 302 may be disposed between the lower crystalline region 301 and the magnetic tunnel junction pattern 400. The amorphous region 302 may be an amorphous state.

The middle crystalline region 303 may be disposed between the lower crystalline region 301 and the amorphous region 302. The middle crystalline region 303 may be in directly contact with the lower crystalline region 301 and the amorphous region 302.

The middle crystalline region 303 may include a conductive material. The middle crystalline region 303 may further include impurities. For example, the middle crystalline region 303 may include the same conductive material and the same impurities as the amorphous region 302. The middle crystalline region 303 may have the same composition ratio as the amorphous region 302.

The middle crystalline region 303 may be a crystalline state. A crystalline structure of the middle crystalline region 303 may be influenced by the lower crystalline region 301. For example, the middle crystalline region 303 may have the same crystalline structure as the lower crystalline region 301. A vertical thickness of the middle crystalline region 303 may be smaller than a vertical thickness of the lower crystalline region 301.

The upper crystalline region 304 may be disposed between the amorphous region 302 and the magnetic tunnel junction pattern 400. The upper crystalline region 304 may be in directly contact with the amorphous region 302 and the seed pattern 410. A level of an upper surface of the upper crystalline region 304 may be same as a level of an upper surface of the lower interlayer insulating layer 200.

The upper crystalline region 304 may include a conductive material and impurities. For example, the upper crystalline region 304 may include the same conductive material and the same impurities as the amorphous region 302. The upper crystalline region 304 may have the same composition ratio as the amorphous region 302.

The upper crystalline region 304 may be a crystalline state. A crystalline structure of the upper crystalline region 304 may be influenced by the magnetic tunnel junction pattern 400. For example, the upper crystalline region 304 may have the same crystalline structure as the seed pattern 410 of the magnetic tunnel junction pattern 400.

A vertical thickness of the upper crystalline region 304 may be smaller than a vertical thickness of the lower crystalline region 301. For example, the vertical thickness of the upper crystalline region 304 may be the same as the vertical thickness of the middle crystalline region 303.

In the magnetic memory device according to the embodiment, the contact plug 300 may include the amorphous region 302 disposed near the magnetic tunnel junction pattern 400. Thus, in the magnetic memory device according to the embodiment, an influence of the contact plug 300 on the magnetic tunnel junction pattern 400 may be prevented without increasing an overall height.

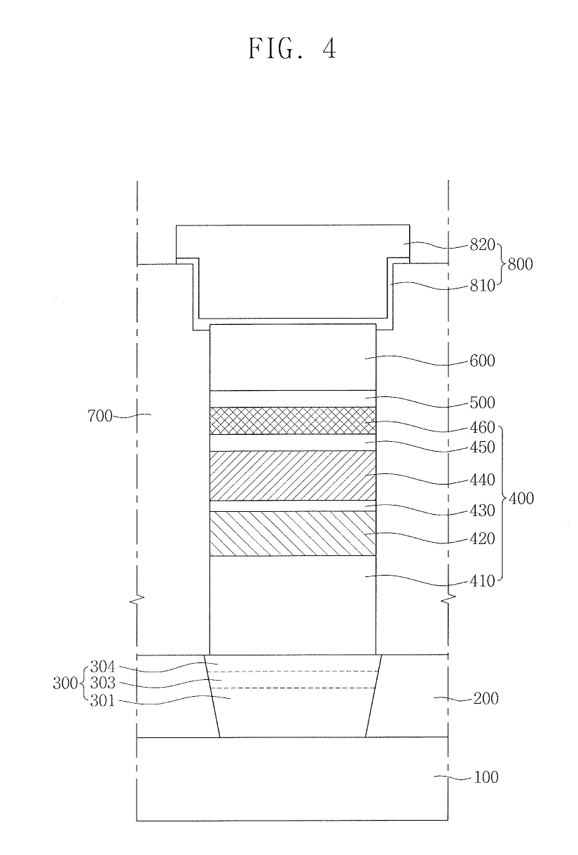

FIG. 4 is a cross-sectional view schematically illustrating a magnetic memory device according to an embodiment.

Referring to FIG. 4, the magnetic memory device according to the embodiment may include a substrate 100, a lower interlayer insulating layer 200, a contact plug 300, a magnetic tunnel junction pattern 400, a capping pattern 500, a metal mask pattern 600, an upper interlayer insulating layer 700, and an upper electrode 800.

The magnetic tunnel junction pattern 400 may include a seed pattern 410, a lower pinned magnetic pattern 420, a spacer 430, an upper pinned magnetic pattern 440, a tunnel barrier pattern 450, and a free magnetic pattern 460. The upper electrode 800 may include an upper barrier pattern 810 and an upper conductive pattern 820.

The contact plug 300 may include a lower crystalline region 301, a middle crystalline region 303, and an upper crystalline region 304.

The lower crystalline region 301, the middle crystalline region 303, and the upper crystalline region 304 may be a crystalline state. The middle crystalline region 303 may be located between the lower crystalline region 301 and the upper crystalline region 304. The middle crystalline region 303 may directly contact the lower crystalline region 301 and the upper crystalline region 304.

The middle crystalline region 303 may have the same crystalline structure as the lower crystalline region 301. The upper crystalline region 304 may have a different crystalline structure from the middle crystalline region 303. For example, the upper crystalline region 304 may have the same crystalline structure as the seed pattern 410.

In the magnetic memory device according to the embodiment, the contact plug 300 may include the upper crystalline region 304 having the same crystalline structure as the seed pattern 410 of the magnetic tunnel junction pattern 400. Thus, in the magnetic memory device according to the embodiment, a change of electromagnetic characteristics of the magnetic tunnel junction pattern 400 caused by the contact plug 300 may be prevented without increasing an overall height.

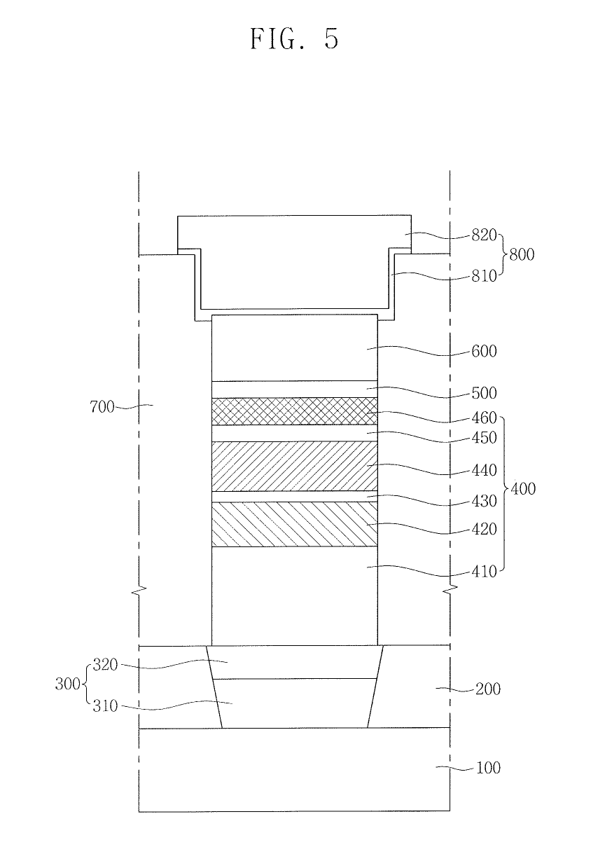

FIG. 5 is a cross-sectional view schematically illustrating a magnetic memory device according to an embodiment.

Referring to FIG. 5, the magnetic memory device according to the embodiment may include a substrate 100, a lower interlayer insulating layer 200, a contact plug 300, a magnetic tunnel junction pattern 400, a capping pattern 500, a metal mask pattern 600, an upper interlayer insulating layer 700, and an upper electrode 800.

The magnetic tunnel junction pattern 400 may include a seed pattern 410, a lower pinned magnetic pattern 420, a spacer 430, an upper pinned magnetic pattern 440, a tunnel barrier pattern 450, and a free magnetic pattern 460. The upper electrode 800 may include an upper barrier pattern 810 and an upper conductive pattern 820.

The contact plug 300 may include a lower plug 310 and an upper plug 320. The lower interlayer insulating layer 200 may surround the lower plug 310 and the upper plug 320.

The lower plug 310 may be located close to the substrate 100. The lower plug 310 may include a conductive material. For example, the lower plug 310 may include a metal such as Cu, W, and Ti. The lower plug 310 may further include impurities. For example, the lower plug 310 may include a metal nitride such as WN and TiN. The lower plug 310 may be a crystalline state.

The upper plug 320 may be located on the lower plug 310. An upper surface of the upper plug 320 may be at the same level as an upper surface of the lower interlayer insulating layer 200. The magnetic tunnel junction pattern 400 may directly contact the upper plug 320.

The upper plug 320 may include a conductive material. A conductive material of the upper plug 320 may be different from a conductive material of the lower plug 310. The upper plug 320 may further include impurities. For example, the upper plug 320 may include a metal or a metal nitride.

The upper plug 320 may be an amorphous state. A vertical thickness of the upper plug 320 may be smaller than a vertical thickness of the lower plug 310.

In the magnetic memory device according to an embodiment, the contact plug 300 may include the lower plug 310 which is crystalline and an upper plug 320 which is amorphous. That is, in the magnetic memory device according to the embodiment, an influence of the lower plug 310 on the magnetic tunnel junction pattern 400 may be prevented by the upper plug 320. Thus, in the magnetic memory device according to the embodiment, electromagnetic characteristics of the magnetic tunnel junction pattern 400 may be improved without increasing an overall height.

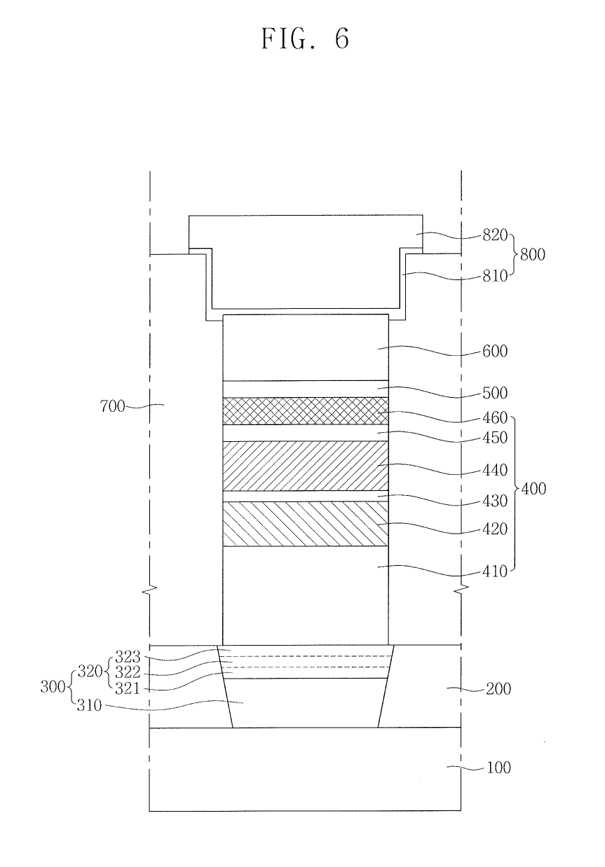

FIG. 6 is a cross-sectional view schematically illustrating a magnetic memory device according to an embodiment.

Referring to FIG. 6, the magnetic memory device according to the embodiment may include a substrate 100, a lower interlayer insulating layer 200, a contact plug 300 having a lower plug 310 and an upper plug 320, a magnetic tunnel junction pattern 400 having a seed pattern 410, a lower pinned magnetic pattern 420, a spacer 430, an upper pinned magnetic pattern 440, a tunnel barrier pattern 450 and a free magnetic pattern 460, a capping pattern 500, a metal mask pattern 600, an upper interlayer insulating layer 700, and an upper electrode 800 having an upper barrier pattern 810 and an upper conductive pattern 820.

The upper plug 320 may be located on the lower plug 310. A vertical thickness of the upper plug 320 may be smaller than a vertical thickness of the lower plug 310. The upper plug 320 may include a lower crystalline region 321, an amorphous region 322, and an upper crystalline region 323.

The lower crystalline region 321 may be located close to the lower plug 310. The lower crystalline region 321 may directly contact the lower plug 310. The lower crystalline region 321 may include a different conductive material from the lower plug 310. The lower crystalline region 321 may further include impurities.

The lower crystalline region 321 may have a crystalline structure. A crystalline structure of the lower crystalline region 321 may be influenced by the lower plug 310. For example, the lower crystalline region 321 may have the same crystalline structure as the lower plug 310.

The amorphous region 322 may be located between the lower crystalline region 321 and the upper crystalline region 323. The amorphous region 322 may directly contact the lower crystalline region 321 and the upper crystalline region 323.

The amorphous region 322 may include the same conductive material as the lower crystalline region 321. The amorphous region 322 may include the same impurities as the lower crystalline region 321. For example, the amorphous region 322 may have the same composition ratio as the lower crystalline region 321. The amorphous region 322 may have an amorphous structure.

The upper crystalline region 323 may be located between the amorphous region 322 and the magnetic tunnel junction pattern 400. The upper crystalline region 323 may directly contact the seed pattern 410. An upper surface of the upper crystalline region 323 may be coplanar with an upper surface of the lower interlayer insulating layer 200.

The upper crystalline region 323 may include the same conductive material and the same impurities as the amorphous region 322. For example, the upper crystalline region 323 may have the same composition ratio as the amorphous region 322.

The upper crystalline region 323 may have a crystalline structure. A crystalline structure of the upper crystalline region 323 may be influenced by the seed pattern 410. For example, the upper crystalline region 323 may have the same crystalline structure as the seed pattern 410. A vertical thickness of the upper crystalline region 323 may be the same as a vertical thickness of the lower crystalline region 321.

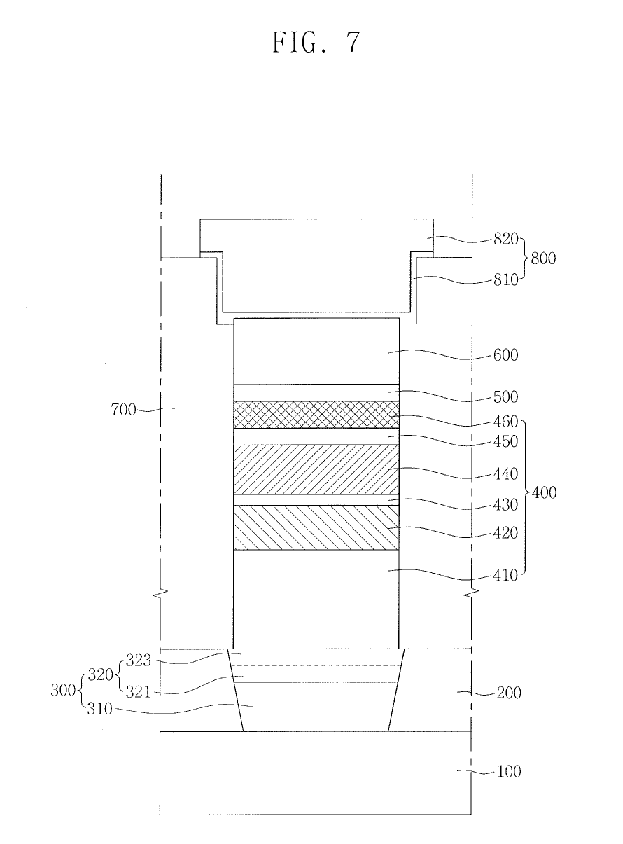

FIG. 7 is a cross-sectional view schematically illustrating a magnetic memory device according to an embodiment.

Referring to FIG. 7, the magnetic memory device according to the embodiment may include a substrate 100, a lower interlayer insulating layer 200, a contact plug 300 having a lower plug 310 and an upper plug 320, a magnetic tunnel junction pattern 400 having a seed pattern 410, a lower pinned magnetic pattern 420, a spacer 430, an upper pinned magnetic pattern 440, a tunnel barrier pattern 450 and a free magnetic pattern 460, a capping pattern 500, a metal mask pattern 600, an upper interlayer insulating layer 700, and an upper electrode 800 having an upper barrier pattern 810 and an upper conductive pattern 820.

The upper plug 320 may be located on the lower plug 310. The upper plug 320 may include a lower crystalline region 321 and an upper crystalline region 323.

The lower crystalline region 321 may directly contact the lower plug 310. The upper crystalline region 323 may directly contact the lower crystalline region 321 and the magnetic tunnel junction pattern 400. The upper crystalline region 323 may have a different crystalline structure from the lower crystalline region 321.

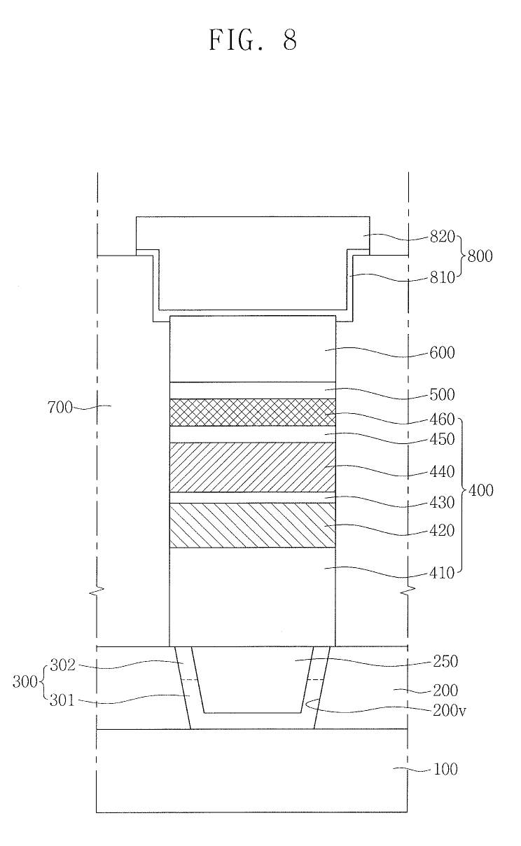

FIG. 8 is a cross-sectional view schematically illustrating a magnetic memory device according to an embodiment.

Referring to FIG. 8, the magnetic memory device according to the embodiment may include a substrate 100, a lower interlayer insulating layer 200, a core pattern 250, a contact plug 300, a magnetic tunnel junction pattern 400, a capping pattern 500, a metal mask pattern 600, an upper interlayer insulating layer 700, and an upper electrode 800.

The contact plug 300 may include a lower crystalline region 301 and an amorphous region 302. The magnetic tunnel junction pattern 400 may include a seed pattern 410, a lower pinned magnetic pattern 420, a spacer 430, an upper pinned magnetic pattern 440, a tunnel barrier pattern 450, and a free magnetic pattern 460. The upper electrode 800 may include an upper barrier pattern 810 and an upper conductive pattern 820.

A horizontal width of an upper surface of the contact plug 300 may be smaller than a horizontal width of a lower surface of the magnetic tunnel junction pattern 400. The magnetic tunnel junction pattern 400 may completely cover an upper surface of the amorphous region 302 of the contact plug 300.

The core pattern 250 may be located on the contact plug 300. The core pattern 250 may be located in a lower via hole 200v of the lower interlayer insulating layer 200. The contact plug 300 may be located between the lower interlayer insulating layer 200 and the core pattern 250.

A level of an upper surface of the core pattern 250 may be the same as a level of an upper surface of the amorphous region 302 of the contact plug 300. The upper surface of the core pattern 250 may be coplanar with an upper surface of the lower interlayer insulating layer 200.

A level of a lower surface of the core pattern 250 may be lower than a level of a lowest level of the amorphous region 302 of the contact plug 300. The amorphous region 302 of the contact plug 300 may be located on a side surface of the core pattern 250.

The core pattern 250 may include an insulating material. For example, the core pattern 250 may include silicon oxide.

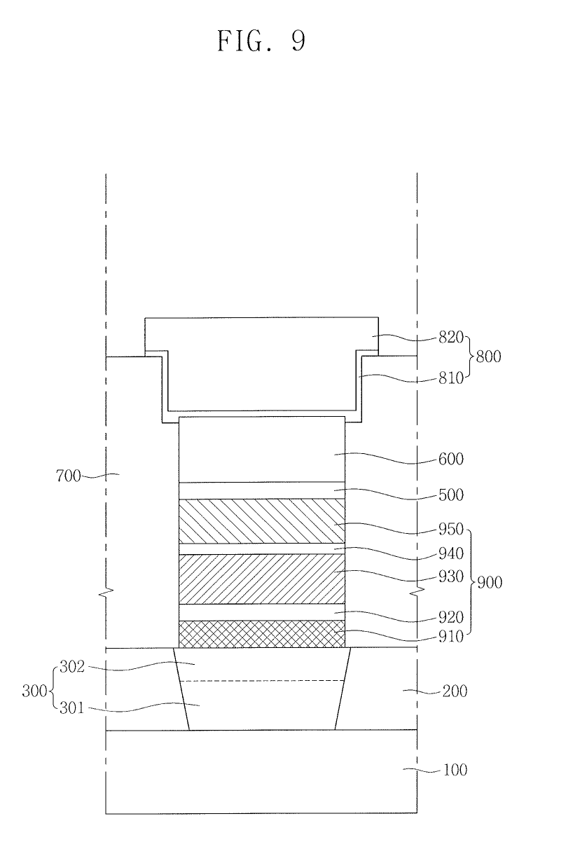

FIG. 9 is a cross-sectional view schematically illustrating a magnetic memory device according to an embodiment.

Referring to FIG. 9, the magnetic memory device according to the embodiment may include a substrate 100, a lower interlayer insulating layer 200, a contact plug 300, a capping pattern 500, a metal mask pattern 600, an upper interlayer insulating layer 700, an upper electrode 800, and a magnetic tunnel junction pattern 900.

The contact plug 300 may include a lower crystalline region 301 and an amorphous region 302. The upper electrode 800 may include an upper barrier pattern 810 and an upper conductive pattern 820.

The magnetic tunnel junction pattern 900 may be located on the amorphous region 302 of the contact plug 300. The magnetic tunnel junction pattern 900 may include a free magnetic pattern 910, a tunnel barrier pattern 920, a lower pinned magnetic pattern 930, a spacer 940, and an upper pinned magnetic pattern 950.

The free magnetic pattern 910 may be located close to the contact plug 300. The free magnetic pattern 910 may directly contact the amorphous region 302 of the contact plug 300.

The free magnetic pattern 910 may include a magnetic material and an amorphized material. For example, the free magnetic pattern 910 may include at least one among Co, Fe, and Ni, and one among Pt, Pd, Ru, and Ta and one among B, P, As, and Bi.

The free magnetic pattern 910 may have a vertical magnetization characteristic. A magnetization direction of the free magnetic pattern 910 may be influenced and changed by an external magnetic field. For example, the magnetization direction of the free magnetic pattern 910 may be changed by a magnetic field formed between the contact plug 300 and the upper electrode 800.

The tunnel barrier pattern 920 may be located on the free magnetic pattern 910. The tunnel barrier pattern 920 may include a non-magnetic material. For example, the tunnel barrier pattern 920 may include MgO.

The tunnel barrier pattern 920 may have an influence on a crystalline structure of the free magnetic pattern 910. For example, the free magnetic pattern 910 may have the same crystalline structure as the tunnel barrier pattern 920.

The lower pinned magnetic pattern 930 may be located on the tunnel barrier pattern 920. The lower pinned magnetic pattern 930 may include a magnetic material and an amorphized material. For example, the lower pinned magnetic pattern 930 may include at least one among Co, Fe, and Ni, and one among Pt, Pd, Ru, and Ta and one among B, P, As, and Bi.

The lower pinned magnetic pattern 930 may have a vertical magnetization characteristic. A magnetization direction of the lower pinned magnetic pattern 930 may not be influenced by an external magnetic field. For example, the magnetization direction of the lower pinned magnetic pattern 930 may not be changed by a magnetic field formed between the contact plug 300 and the upper electrode 800.

A crystalline structure of the lower pinned magnetic pattern 930 may be influenced by the tunnel barrier pattern 920. For example, the lower pinned magnetic pattern 930 may have the same crystalline structure as the tunnel barrier pattern 920.

The spacer 940 may be located on the lower pinned magnetic pattern 930. The spacer 940 may include a non-magnetic material. For example, the spacer 940 may include Ru, Ir, Re or Os.

The upper pinned magnetic pattern 950 may be located between the spacer 940 and the capping pattern 500. The upper pinned magnetic pattern 950 may include a magnetic material. For example, the upper pinned magnetic pattern 950 may include one among Pt, Pd, Ru, and Ta and at least one among Co, Fe, and Ni.

The upper pinned magnetic pattern 950 may have a vertical magnetization characteristic. For example, a magnetization direction of the upper pinned magnetic pattern 950 may not be changed by a magnetic field formed between the contact plug 300 and the upper electrode 800.

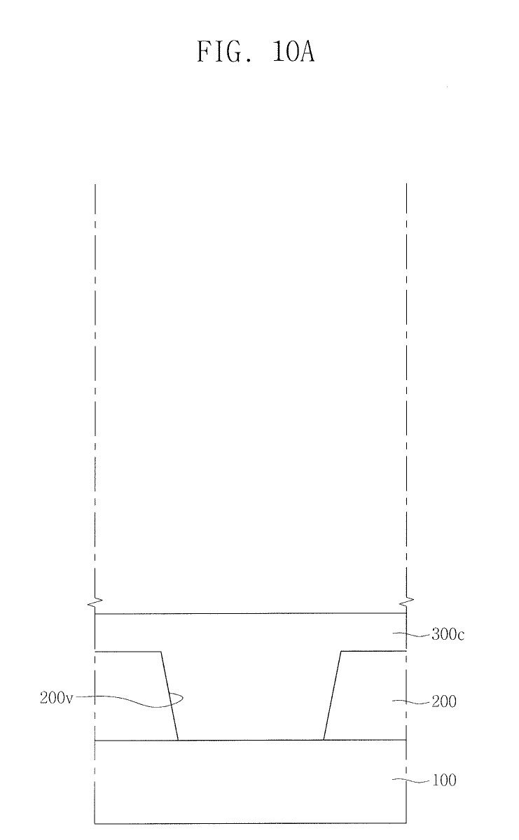

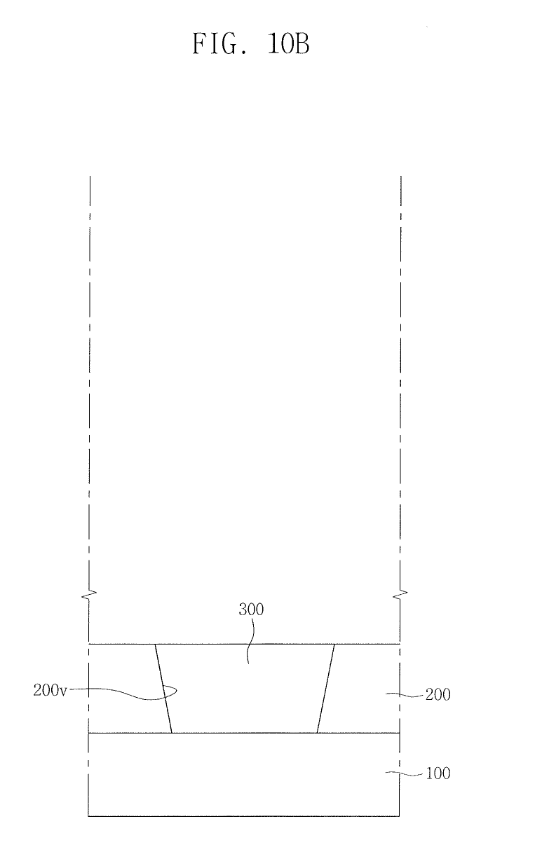

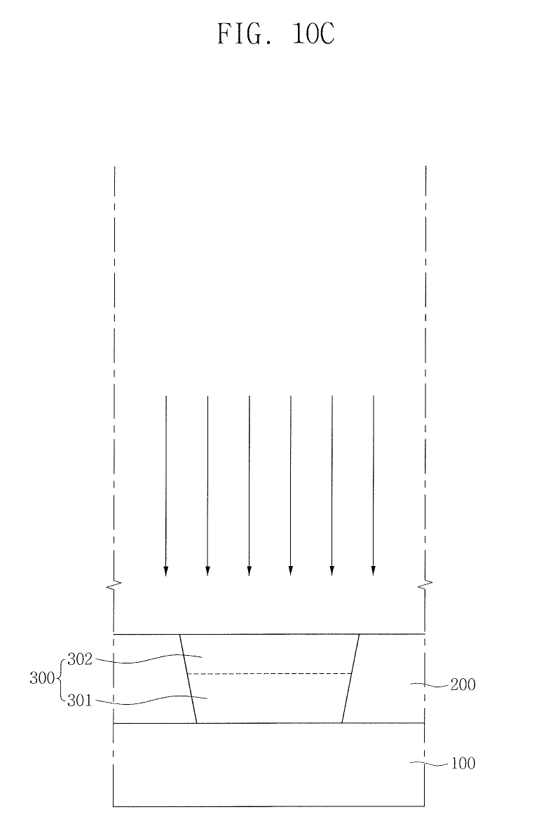

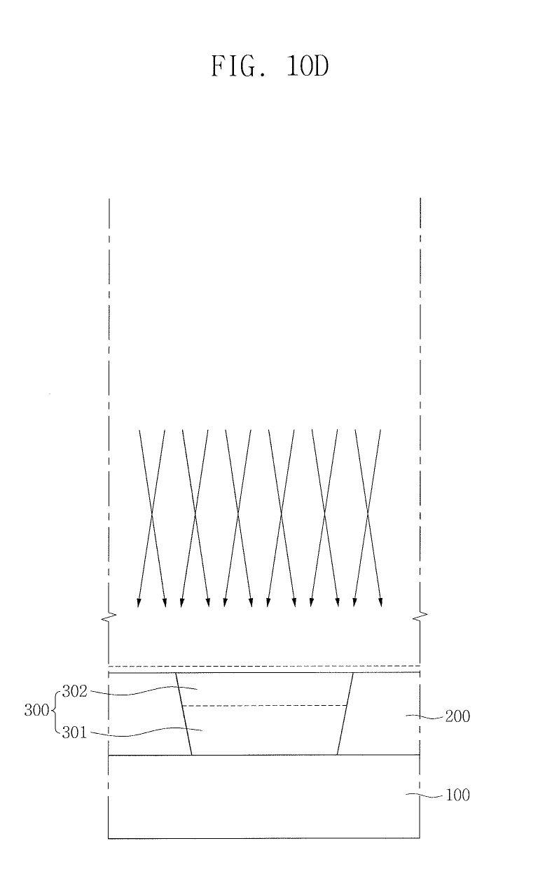

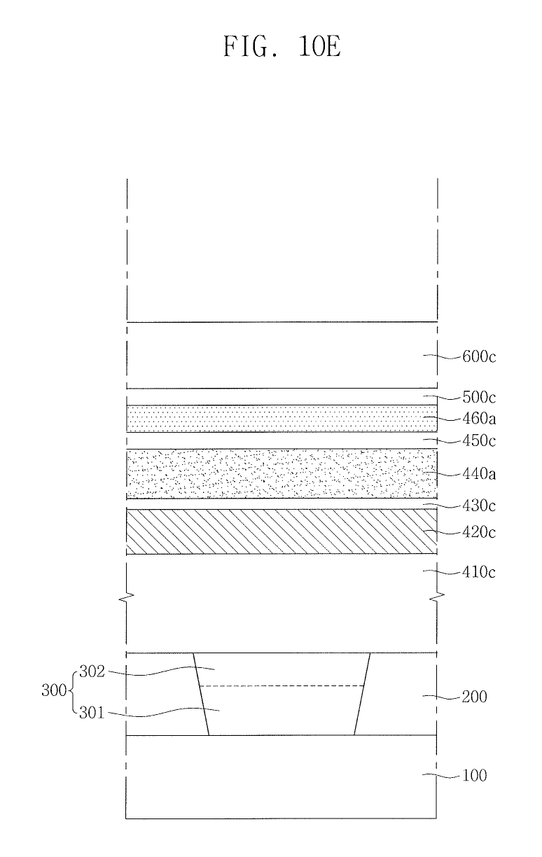

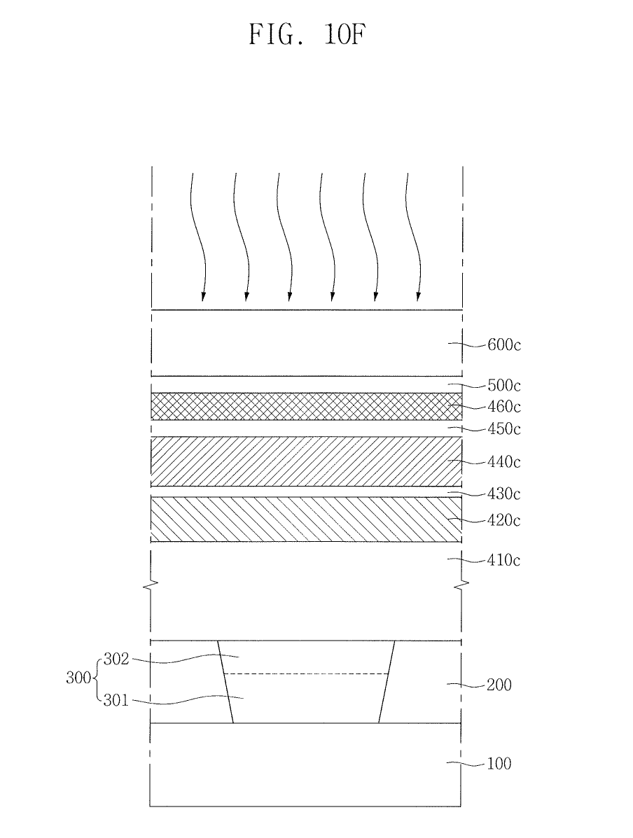

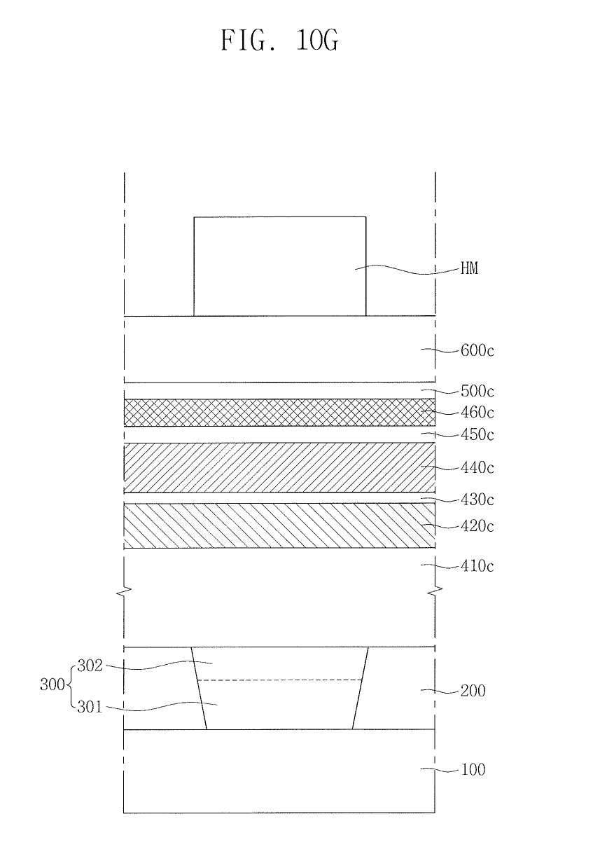

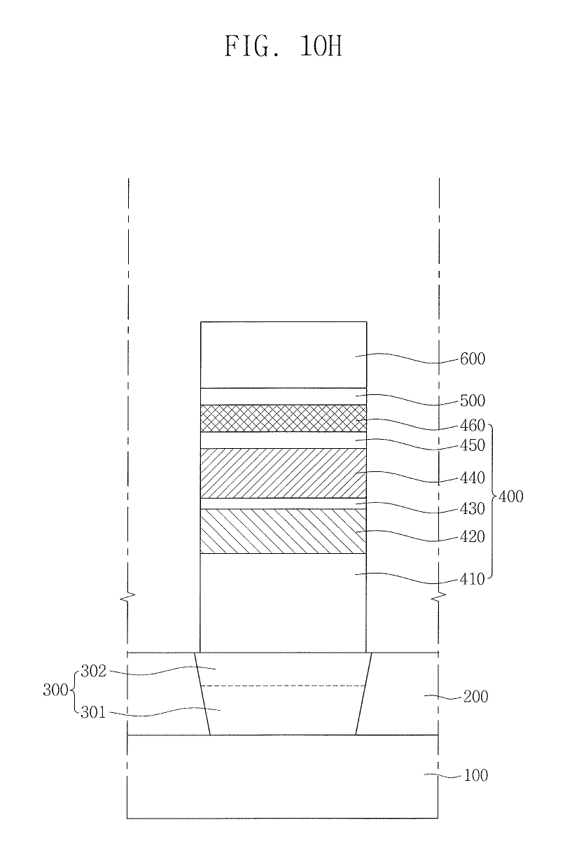

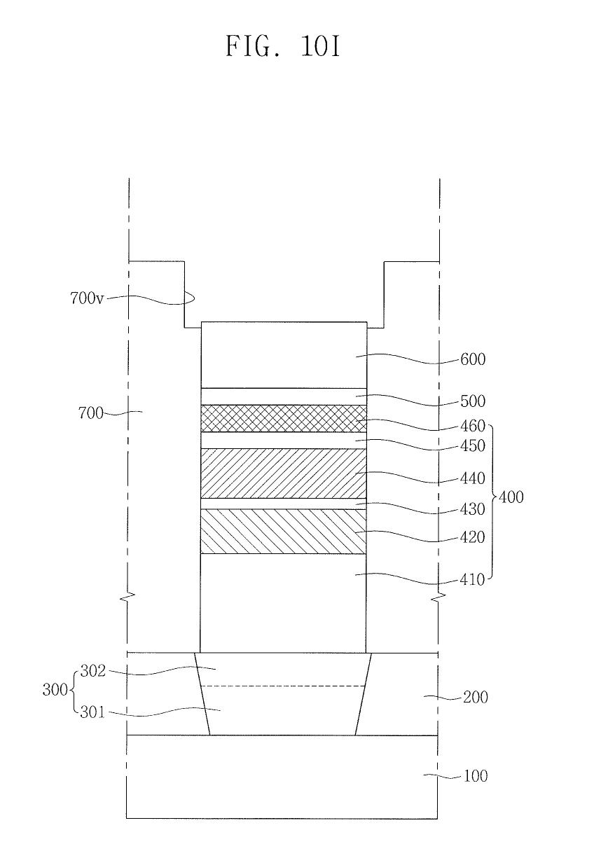

FIGS. 10A to 10J are cross-sectional views sequentially illustrating a method of forming a magnetic memory device according to an embodiment.

Referring to FIGS. 2 and 10A to 10J, the method of forming the magnetic memory device according to the embodiment is described. First, as illustrated in FIG. 10A, the method of forming the magnetic memory device according to the embodiment may include a process of forming a lower interlayer insulating layer 200 on a substrate 100, a process of forming a lower via hole 200v in the lower interlayer insulating layer 200, and a process of forming a plug conductive layer 300c filling the lower via hole 200v of the lower interlayer insulating layer 200.

The process of forming the lower interlayer insulating layer 200 may include a process of forming a layer having an insulating material such as silicon oxide and silicon nitride on the substrate 100.

The process of forming the plug conductive layer 300c may include a process of forming a crystalline layer having a conductive material on the lower interlayer insulating layer 200. For example, the process of forming the plug conductive layer 300c may include a process of filling a crystalline layer having a metal such as Cu, W, and Ti in the lower via hole 200v of the lower interlayer insulating layer 200.

As illustrated in FIG. 10B, the method of forming the magnetic memory device according to the embodiment may include a process of forming a contact plug 300 in the lower via hole 200v of the lower interlayer insulating layer 200.

The process of forming the contact plug 300 may include a process of planarizing the plug conductive layer 300c to expose an upper surface of the lower interlayer insulating layer 200. The process of planarizing the plug conductive layer 300c may include a chemical mechanical polishing (CMP) process.

As illustrated in FIG. 10C, the method of forming the magnetic memory device according to the embodiment may include a process of amorphizing an upper region of the contact plug 300.

The process of amorphizing the upper region of the contact plug 300 may include a process of doping the contact plug 300 with impurities. The process of doping with the impurities may include an ion implantation process. For example, the impurities may include B, As, N, or P.

The contact plug 300 may include a lower crystalline region 301 which is crystalline and an amorphous region 302 which is amorphous located on the lower crystalline region 301 by the process of amorphizing the upper region of the contact plug 300.

As illustrated in FIG. 10D, the method of forming the magnetic memory device according to the embodiment may include a process of flattening an upper surface of the contact plug 300.

For example, the process of flattening the upper surface of the contact plug 300 may include a process of decreasing surface roughness of the upper surface of the contact plug 300. For example, the process of flattening the upper surface of the contact plug 300 may include plasma processing of the upper surface of the lower interlayer insulating layer 200 and the upper surface of the contact plug 300. The plasma processing may include an etch-back processing of the upper surface of the lower interlayer insulating layer 200 and the upper surface of the contact plug 300 using noble gas plasma such as Ar, Xe, or Kr.

A level of the upper surface of the contact plug 300 may be same as a level of the upper surface of the lower interlayer insulating layer 200 by the process of flattening the upper surface of the contact plug 300.

As illustrated in FIG. 10E, the method of forming the magnetic memory device according to the embodiment may include a process of forming a seed layer 410c on the contact plug 300, a process of forming a lower pinned magnetic layer 420c on the seed layer 410c, a process of forming a spacer layer 430c on the lower pinned magnetic layer 420c, a process of forming a preliminary upper pinned magnetic layer 440a on the spacer layer 430c, a process of forming a tunnel barrier layer 450c on the preliminary upper pinned magnetic layer 440a, a process of forming a preliminary free magnetic layer 460a on the tunnel barrier layer 450c, a process of forming a capping layer 500c on the preliminary free magnetic layer 460a, and a process of forming a metal mask layer 600c on the capping layer 500c.

The process of forming the seed layer 410c may include a process of forming a crystalline layer having Ru, Ta or Ti. The process of forming the lower pinned magnetic layer 420c may include a process of forming a crystalline layer having one among Pt, Pd, Ru, and Ta and at least one among Co, Fe, and Ni. The process of forming the spacer layer 430c may include a process of forming a crystalline layer having Ru, Ir, Re, or Os. The process of forming the preliminary upper pinned magnetic layer 440a may include a process of forming an amorphous layer having at least one among Co, Fe, and Ni, and one among Pt, Pd, Ru, and Ta and one among B, P, As, and Bi. The process of forming the tunnel barrier layer 450c may include a process of forming a crystalline layer having MgO. The process of forming the preliminary free magnetic layer 460a may include a process of forming an amorphous layer having at least one among Co, Fe, and Ni, and one among Pt, Pd, Ru, and Ta and one among B, P, As, and Bi. The process of forming the capping layer 500c may include a process of forming at least one layer having one among Cu, Ta, Al, Au, Ti, TiN, and TaN. The process of forming the metal mask layer 600c may include a process of forming a crystalline layer having a metal or a metal nitride.

In the method of forming the magnetic memory device according to the embodiment, the seed layer 410c may be formed on the amorphous region 302 of the contact plug 300. Accordingly, in the method of forming the magnetic memory device according to the embodiment, the seed layer 410c may be formed without being influenced by the lower crystalline region 301 of the contact plug 300. Thus, in the method of forming the magnetic memory device according to the embodiment, the seed layer 410c may be formed to have a crystalline structure based on a unique characteristic. For example, in the method of forming the magnetic memory device according to the embodiment, the seed layer 410c may be formed to have a different crystalline structure from the lower crystalline region 301 of the contact plug 300.

As illustrated in FIG. 10F, the method of forming the magnetic memory device according to the embodiment may include a process of crystallizing the preliminary upper pinned magnetic layer 440a and the preliminary free magnetic layer 460a.

The process of crystallizing the preliminary upper pinned magnetic layer 440a and the preliminary free magnetic layer 460a may include a process of annealing the substrate 100 having the preliminary upper pinned magnetic layer 440a and the preliminary free magnetic layer 460a.

An upper pinned magnetic layer 440c and a free magnetic layer 460c may be formed by a process of forming the upper pinned magnetic layer 440c and the free magnetic layer 460c. A crystalline structure of the upper pinned magnetic layer 440c and a crystalline structure of the free magnetic layer 460c may be influenced by the tunnel barrier pattern 450.

In the method of forming the magnetic memory device according to an embodiment, the amorphous region 302 of the contact plug 300 may remain amorphous after the processes of crystallizing the preliminary upper pinned magnetic layer 440a and the preliminary free magnetic layer 460a have ended. For example, in the method of forming the magnetic memory device according to the embodiment, the processes of crystallizing the preliminary upper pinned magnetic layer 440a and the preliminary free magnetic layer 460a may be performed at a temperature lower than a crystallization temperature of the amorphous region 302 of the contact plug 300. Thus, in the method of forming the magnetic memory device according to the embodiment, the crystallization temperature of the amorphous region 302 of the contact plug 300 may be higher than a crystallization temperature of the upper pinned magnetic layer 440c and a crystallization temperature of the free magnetic layer 460c.

As illustrated in FIG. 10G, the method of forming the magnetic memory device according to the embodiment may include a process of forming a hard mask (HM) pattern on the metal mask layer 600c.

The HM pattern may be formed on an upper surface of the contact plug 300. A horizontal width of the HM pattern may be smaller than a horizontal width of the upper surface of the contact plug 300.

As illustrated in FIG. 10H, the method of forming the magnetic memory device according to the embodiment may use the HM pattern and include processes of sequentially patterning the metal mask layer 600c, the capping layer 500c, the free magnetic layer 460c, the tunnel barrier layer 450c, the upper pinned magnetic layer 440c, the spacer layer 430c, the lower pinned magnetic layer 420c, and the seed layer 410c and a process of removing the HM pattern.

A metal mask pattern 600 may be formed by the process of patterning the metal mask layer 600c. A capping pattern 500 may be formed by the process of patterning the capping layer 500c. A side surface of the capping pattern 500 may be vertically aligned with a side surface of the metal mask pattern 600.

A magnetic tunnel junction pattern 400 may be formed by processes of sequentially patterning the free magnetic layer 460c, the tunnel barrier layer 450c, the upper pinned magnetic layer 440c. the spacer layer 430c, the lower pinned magnetic layer 420c, and the seed layer 410c. The magnetic tunnel junction pattern 400 may include a seed pattern 410, a lower pinned magnetic pattern 420, a spacer 430, an upper pinned magnetic pattern 440, a tunnel barrier pattern 450, and a free magnetic pattern 460. A side surface of the magnetic tunnel junction pattern 400 may be vertically aligned with a side surface of the capping pattern 500.

A horizontal width of a lower surface of the magnetic tunnel junction pattern 400 may be smaller than a horizontal width of the upper surface of the contact plug 300.

As illustrated in FIG. 10I, the method of forming the magnetic memory device according to the embodiment may include a process of forming an upper interlayer insulating layer 700 on the lower interlayer insulating layer 200 and a process of forming an upper via hole 700v in the upper interlayer insulating layer 700.

The process of forming the upper interlayer insulating layer 700 may include processes of covering the magnetic tunnel junction pattern 400, the capping pattern 500, and the metal mask pattern 600 with a layer having an insulating material such as silicon oxide and silicon nitride.

The process of forming the upper via hole 700v may include a process of exposing an upper surface of the metal mask pattern 600.

As illustrated in FIG. 10J, the method of forming the magnetic memory device according to the embodiment may include a process of forming an upper electrode layer 800c configured to fill the upper via hole 700v of the upper interlayer insulating layer 700.

The process of forming the upper electrode layer 800c may include a process of forming an upper barrier layer 810c on the upper interlayer insulating layer 700 and a process of forming an upper conductive layer 820c on the upper barrier layer 810c.

The upper barrier layer 810c may be formed to have a uniform thickness on a surface of the upper interlayer insulating layer 700. The process of forming the upper barrier layer 810c may include a process of forming a crystalline layer having a conductive material such as a metal nitride.

A level of an upper surface of the upper conductive layer 820c may be higher than a level of an upper surface of the upper interlayer insulating layer 700. The process of forming the upper conductive layer 820c may include a process of forming a crystalline layer having a conductive material such as a metal.

As illustrated in FIG. 2, the method of forming the magnetic memory device according to the embodiment may include a process of forming an upper electrode 800 on the metal mask pattern 600.

The process of forming the upper electrode 800 may include a process of patterning the upper electrode layer 800c. The process of patterning the upper electrode layer 800c may include processes of sequentially patterning the upper conductive layer 820c and the upper barrier layer 810c.

A method of forming a magnetic memory device according to an embodiment may include a process of forming an amorphous region in a contact plug and a process of forming a magnetic tunnel junction pattern on the amorphous region of the contact plug. Therefore, in the method of forming the magnetic memory device according to the embodiment, a crystalline characteristic of a contact plug being transferred to a magnetic tunnel junction pattern may be prevented without forming an additional insertion layer. Thus, in the method of forming the magnetic memory device according to the embodiment, a process time and a cost may be reduced. Also, in the method of forming the magnetic memory device according to the embodiment, a degree of integration and reliability may be improved.

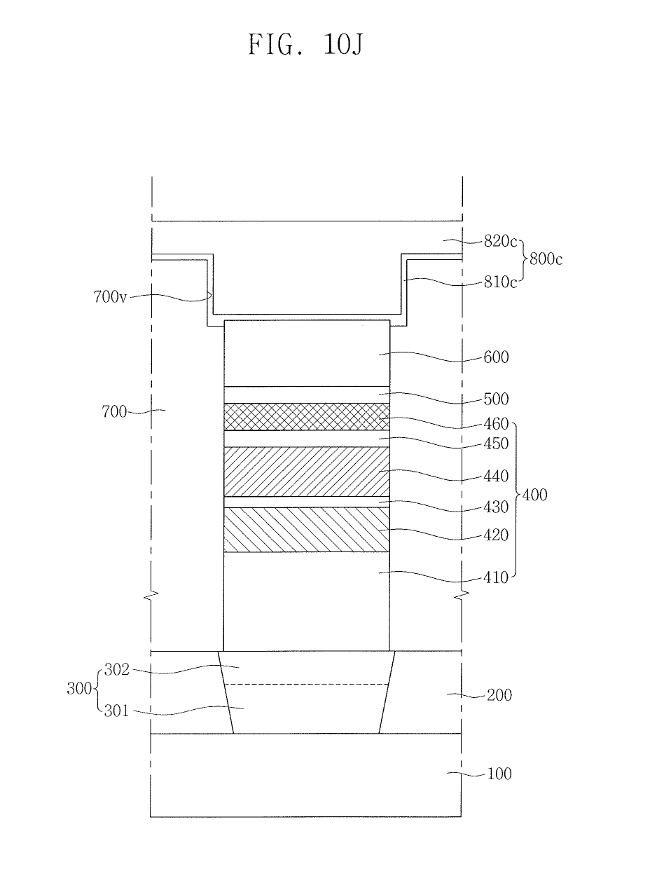

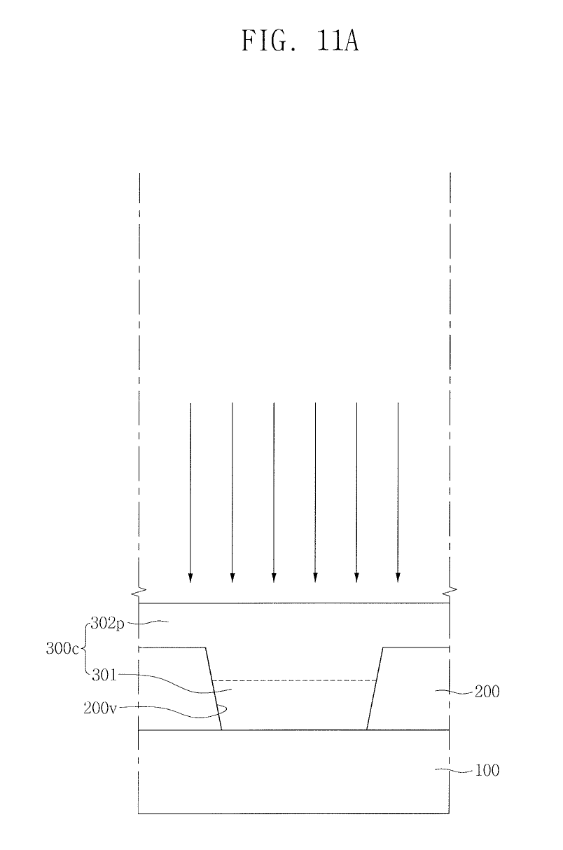

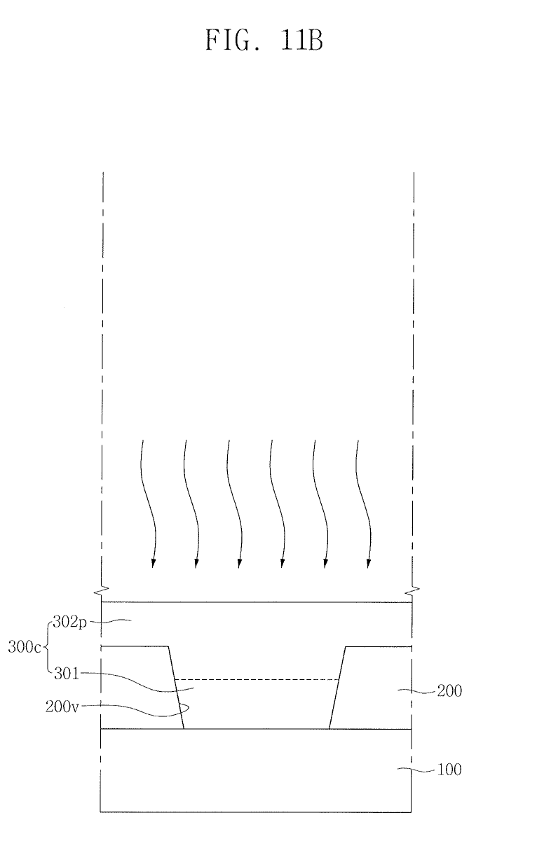

FIGS. 11A to 11C are cross-sectional views sequentially illustrating a method of forming a magnetic memory device according to an embodiment.

Referring to FIGS. 3 and 11A to 11C, the method of forming the magnetic memory device according to the embodiment is described. First, as illustrated in FIG. 11A, the method of forming the magnetic memory device according to the embodiment may include a process of forming a lower interlayer insulating layer 200 on a substrate 100, a process of forming a lower via hole 200v in the lower interlayer insulating layer 200, a process of forming a plug conductive layer 300c configured to fill the lower via hole 200v of the lower interlayer insulating layer 200, and a process of doping the plug conductive layer 300c with impurities.

The plug conductive layer 300c may include a lower crystalline region 301 which is crystalline and an impurity region 302p which is amorphous by the process of doping the plug conductive layer 300c with the impurities. A level of a lower surface of the impurity region 302p may be lower than a level of an upper surface of the lower interlayer insulating layer 200.

As illustrated in FIG. 11B, the method of forming the magnetic memory device according to the embodiment may include a process of activating the impurities which doped the plug conductive layer 300c.

The process of activating the impurities which doped the plug conductive layer 300c may include a process of annealing the substrate 100 in which the impurity region 302p is formed.

As illustrated in FIG. 11C, the method of forming the magnetic memory device according to the embodiment may include a process of forming a contact plug 300 by planarizing the plug conductive layer 300c, a process of forming a seed layer 410c on the contact plug 300, a process of forming a lower pinned magnetic layer 420c on the seed layer 410c, a process of forming a spacer layer 430c on the lower pinned magnetic layer 420c, a process of forming a preliminary upper pinned magnetic layer on the spacer layer 430c, a process of forming a tunnel barrier layer 450c on the preliminary upper pinned magnetic layer, a process of forming a preliminary free magnetic layer on the tunnel barrier layer 450c, a process of forming a capping layer 500c on the preliminary free magnetic layer, a process of forming a metal mask layer 600c on the capping layer 500c, and processes of forming an upper pinned magnetic layer 440c and a free magnetic layer 460c by crystallizing the preliminary upper pinned magnetic layer and the preliminary free magnetic layer.

In the method of forming the magnetic memory device according to an embodiment, an amorphous region 302 of the contact plug 300 may be partially crystallized by processes of forming an upper pinned magnetic layer 440c and a free magnetic layer 460c. For example, in the method of forming the magnetic memory device according to the embodiment, the contact plug 300 may include a lower crystalline region 301, an amorphous region 302, a middle crystalline region 303, and an upper crystalline region 304 by the processes of forming the upper pinned magnetic layer 440c and the free magnetic layer 460c.

The middle crystalline region 303 may be a lower region of the amorphous region 302 crystallized by an influence of the lower crystalline region 301. The middle crystalline region 303 may be formed to have the same crystalline structure as the lower crystalline region 301.

The upper crystalline region 304 may be an upper region of the amorphous region 302 crystallized by an influence of the seed layer 410c. The upper crystalline region 304 may be formed to have the same crystalline structure as the seed layer 410c. For example, the upper crystalline region 304 may be formed to have a different crystalline structure from the middle crystalline region 303.

As illustrated in FIG. 3, the method of forming the magnetic memory device according to the embodiment may include processes of forming a magnetic tunnel junction pattern 400, a capping pattern 500, and a metal mask pattern 600, a process of forming an upper interlayer insulating layer 700, and a process of forming an upper electrode 800.

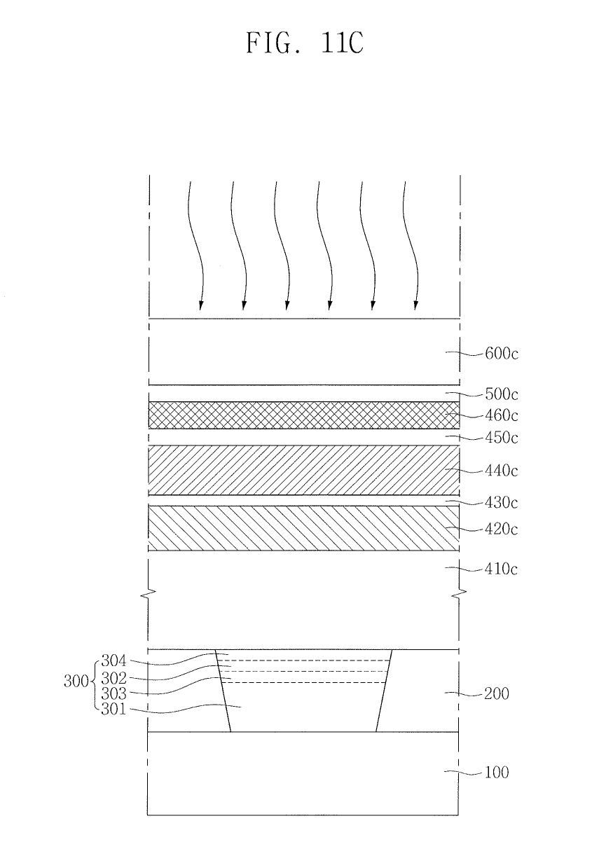

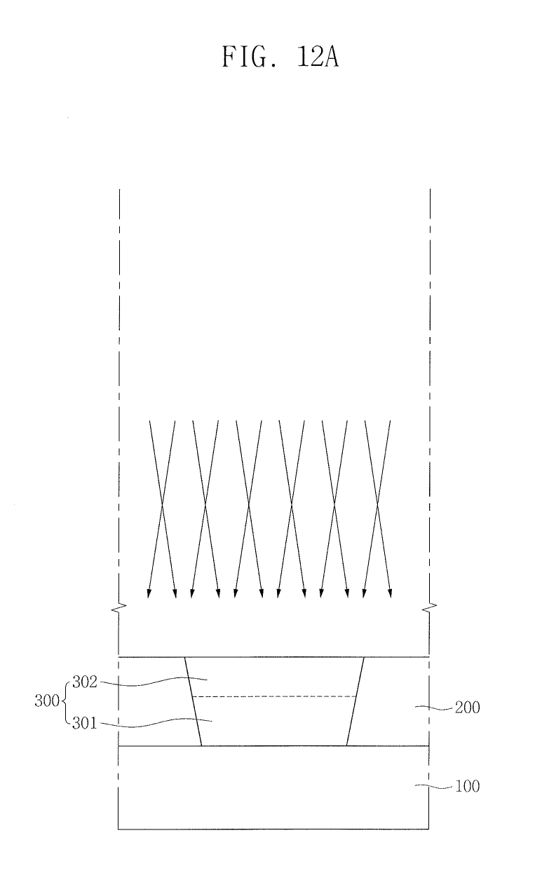

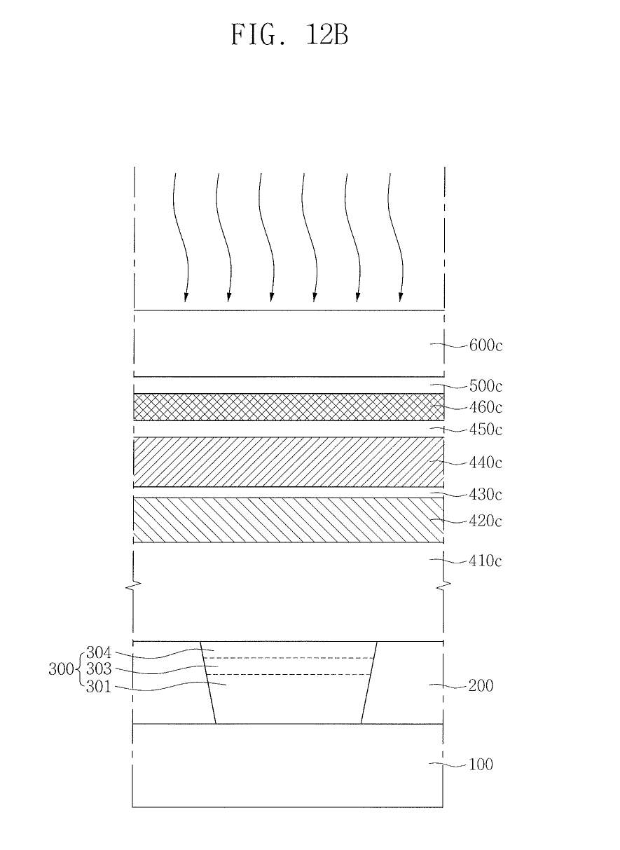

FIGS. 12A and 12B are cross-sectional views sequentially illustrating a method of forming a magnetic memory device according to an embodiment.

Referring to FIGS. 4, 12A and 12B, the method of forming the magnetic memory device according to the embodiment is described. First, as illustrated in FIG. 12A, the method of forming the magnetic memory device according to the embodiment may include a process of forming a lower interlayer insulating layer 200 on a substrate 100, a process of forming a lower via hole 200v in the lower interlayer insulating layer 200, a process of forming a contact plug 300 in the lower via hole 200v of the lower interlayer insulating layer 200, and a process of plasma damaging an upper region of the contact plug 300.

An amorphous region 302 may be formed in the upper region of the contact plug 300 by the process of plasma damaging. The contact plug 300 may include a lower crystalline region 301 which is crystalline and an amorphous region 302, which is amorphous by the process of plasma damaging, located on the lower crystalline region 301.

As illustrated in FIG. 12B, the method of forming the magnetic memory device according to the embodiment may include a process of forming a seed layer 410c on the contact plug 300, a process of forming a lower pinned magnetic layer 420c on the seed layer 410c, a process of forming a spacer layer 430c on the lower pinned magnetic layer 420c, a process of forming a preliminary upper pinned magnetic layer on the spacer layer 430c, a process of forming a tunnel barrier layer 450c on the preliminary upper pinned magnetic layer, a process of forming a preliminary free magnetic layer on the tunnel barrier layer 450c, a process of forming a capping layer 500c on the preliminary free magnetic layer, a process of forming a metal mask layer 600c on the capping layer 500c, and processes of forming an upper pinned magnetic layer 440c and a free magnetic layer 460c by crystallizing the preliminary upper pinned magnetic layer and the preliminary free magnetic layer.

In the method of forming the magnetic memory device according to the embodiment, the entire amorphous region 302 of the contact plug 300 may be crystallized by processes of forming an upper pinned magnetic layer 440c and a free magnetic layer 460c. For example, in the method of forming the magnetic memory device according to the embodiment, the contact plug 300 may include a lower crystalline region 301, a middle crystalline region 303, and an upper crystalline region 304 by the processes of forming the upper pinned magnetic layer 440c and the free magnetic layer 460c. The middle crystalline region 303 may be in directly contact with the lower crystalline region 301 and the upper crystalline region 304.

As illustrated in FIG. 4, the method of forming the magnetic memory device according to the embodiment may include processes of forming a magnetic tunnel junction pattern 400, a capping pattern 500, and a metal mask pattern 600, a process of forming an upper interlayer insulating layer 700, and a process of forming an upper electrode 800.

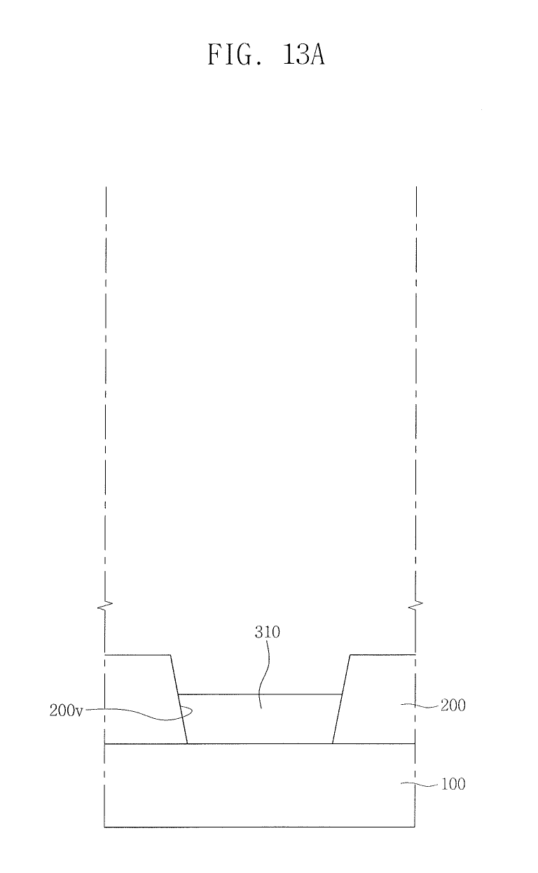

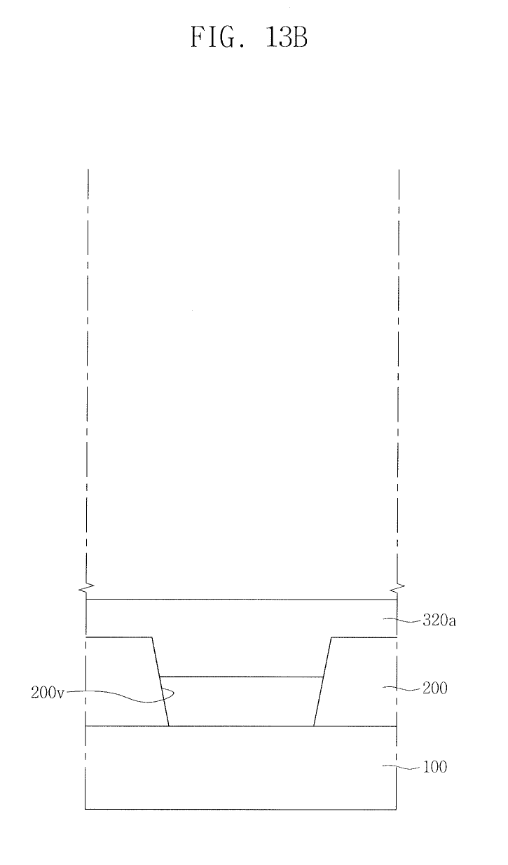

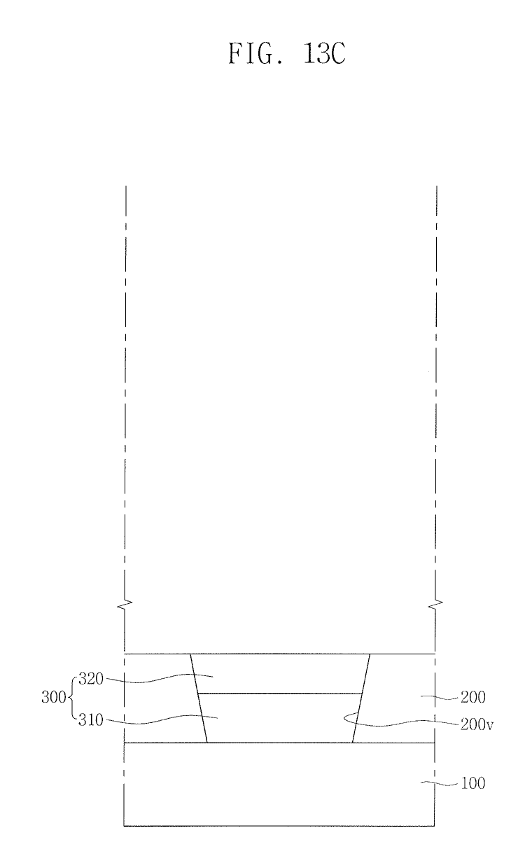

FIGS. 13A to 13D are cross-sectional views sequentially illustrating a method of forming a magnetic memory device according to an embodiment.

Referring to FIGS. 6 and 13A to 13D, the method of forming the magnetic memory device according to the embodiment is described. First, as illustrated in FIG. 13A, the method of forming the magnetic memory device according to the embodiment may include a process of forming a lower interlayer insulating layer 200 on a substrate 100, a process of forming a lower via hole 200v in the lower interlayer insulating layer 200, and a process of forming a lower plug 310 in the lower via hole 200v of the lower interlayer insulating layer 200.

A level of an upper surface of the lower plug 310 may be lower than a level of an upper surface of the lower interlayer insulating layer 200. The process of forming the lower plug 310 may include a process of forming a lower plug conductive layer, which is crystalline, configured to fill the lower via hole 200v of the lower interlayer insulating layer 200 and a process of etch-back processing of the lower plug conductive layer.

As illustrated in FIG. 13B, the method of forming the magnetic memory device according to the embodiment may include a process of forming an upper plug conductive layer 320a on the lower plug 310.

The process of forming the upper plug conductive layer 320a may include a process of forming an amorphous layer having a conductive material on the lower plug 310. A conductive material of the upper plug conductive layer 320a may be different from the conductive material of the lower plug 310. The upper plug conductive layer 320a may further include impurities.

As illustrated in FIG. 13C, the method of forming the magnetic memory device according to the embodiment may include a process of planarizing the upper plug conductive layer 320a to expose an upper surface of the lower interlayer insulating layer 200.

A contact plug 300 may be formed in the lower via hole 200v of the lower interlayer insulating layer 200 by the process of planarizing the upper plug conductive layer 320a. The contact plug 300 may include a lower plug 310 which is crystalline and an upper plug 320, which is amorphous, located on the lower plug 310.

As illustrated in FIG. 13D, the method of forming the magnetic memory device according to the embodiment may include a process of forming a seed layer 410c on the contact plug 300, a process of forming a lower pinned magnetic layer 420c on the seed layer 410c, a process of forming a spacer layer 430c on the lower pinned magnetic layer 420c, a process of forming a preliminary upper pinned magnetic layer on the spacer layer 430c, a process of forming a tunnel barrier layer 450c on the preliminary upper pinned magnetic layer, a process of forming a preliminary free magnetic layer on the tunnel barrier layer 450c, a process of forming a capping layer 500c on the preliminary free magnetic layer, a process of forming a metal mask layer 600c on the capping layer 500c, and processes of forming an upper pinned magnetic layer 440c and a free magnetic layer 460c by crystallizing the preliminary upper pinned magnetic layer and the preliminary free magnetic layer.

In a method of forming a magnetic memory device according to an embodiment, the upper plug 320 may be partially crystallized through processes of forming an upper pinned magnetic layer 440c and a free magnetic layer 460c. For example, in the method of forming the magnetic memory device according to the embodiment, the upper plug 320 may include a lower crystalline region 321, an amorphous region 322, and an upper crystalline region 323 through the processes of forming the upper pinned magnetic layer 440c and the free magnetic layer 460c.

As illustrated in FIG. 6, the method of forming the magnetic memory device according to the embodiment may include processes of forming a magnetic tunnel junction pattern 400, a capping pattern 500, and a metal mask pattern 600, a process of forming an upper interlayer insulating layer 700, and a process of forming an upper electrode 800.

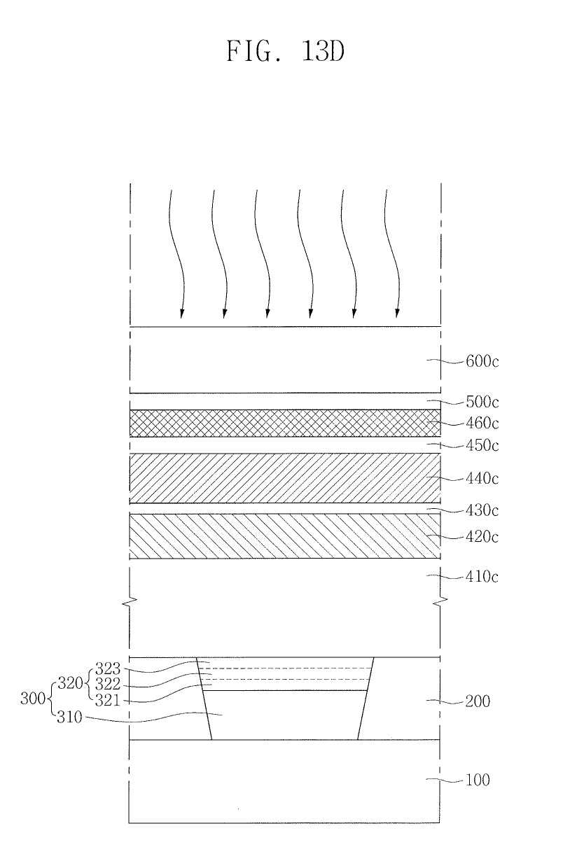

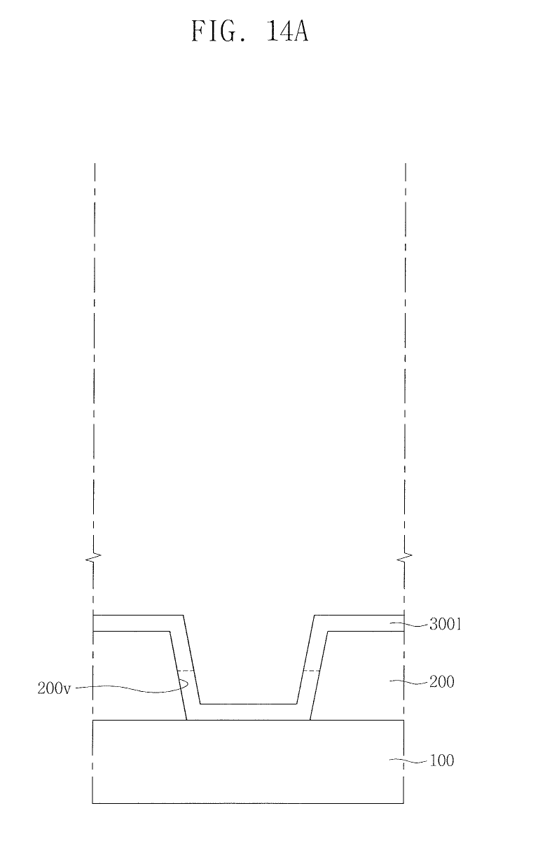

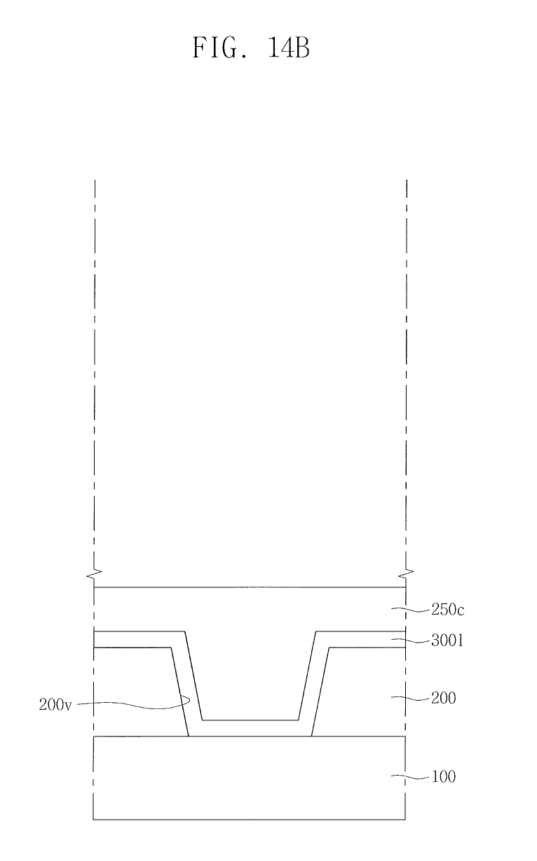

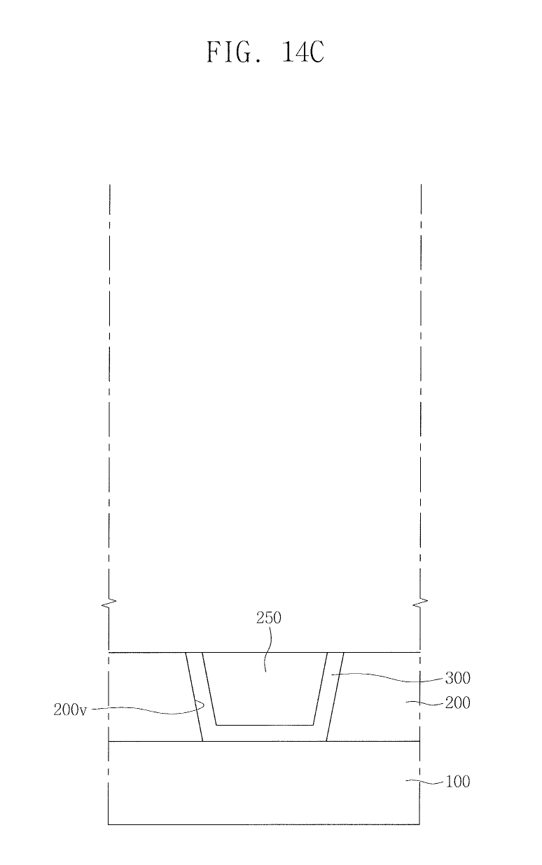

FIGS. 14A to 14D are cross-sectional views sequentially illustrating a method of forming a magnetic memory device according to an embodiment.

Referring to FIGS. 8 and 14A to 14D, the method of forming the magnetic memory device according to the embodiment is described. First, as illustrated in FIG. 14A, the method of forming the magnetic memory device according to the embodiment may include a process of forming a lower interlayer insulating layer 200 having a lower via hole 200v on a substrate 100 and a process of forming a plug conductive layer 3001 on the lower interlayer insulating layer 200.

The plug conductive layer 3001 may be formed to have a uniform thickness on a surface of the lower interlayer insulating layer 200.

As illustrated in FIG. 14B, the method of forming the magnetic memory device according to the embodiment may include a process of forming a core layer 250c on the plug conductive layer 3001.

The process of forming the core layer 250c may include a process of coating with an insulating material. For example, the process of forming the core layer 250c may include a process of forming silicon oxide on the plug conductive layer 3001.

A level of an upper surface of the core layer 250c may be higher than a level of an upper surface of the lower interlayer insulating layer 200.

As illustrated in FIG. 14C, the method of forming the magnetic memory device according to the embodiment may include processes of forming a contact plug 300 and a core pattern 250 in the lower via hole 200v of the lower interlayer insulating layer 200.

The processes of forming the contact plug 300 and the core pattern 250 may include processes of planarizing the plug conductive layer 3001 and the core layer 250c to expose an upper surface of the lower interlayer insulating layer 200.

As illustrated in FIG. 14D, the method of forming the magnetic memory device according to the embodiment may include a process of doping an upper region of the contact plug 300 with impurities.

The contact plug 300 may include a lower crystalline region 301 which is crystalline and an amorphous region 302 which is amorphous by a process of doping with the impurities. The amorphous region 302 of the contact plug 300 may be located on a side surface of the core pattern 250. A lowest level of the amorphous region 302 of the contact plug 300 may be higher than a level of a lower surface of the core pattern 250.

As illustrated in FIG. 8, the method of forming the magnetic memory device according to the embodiment may include a process of flattening the upper surface of the contact plug 300 and processes of forming a magnetic tunnel junction pattern 400, a capping pattern 500, a metal mask pattern 600, an upper interlayer insulating layer 700, and an upper electrode 800 on the contact plug 300.

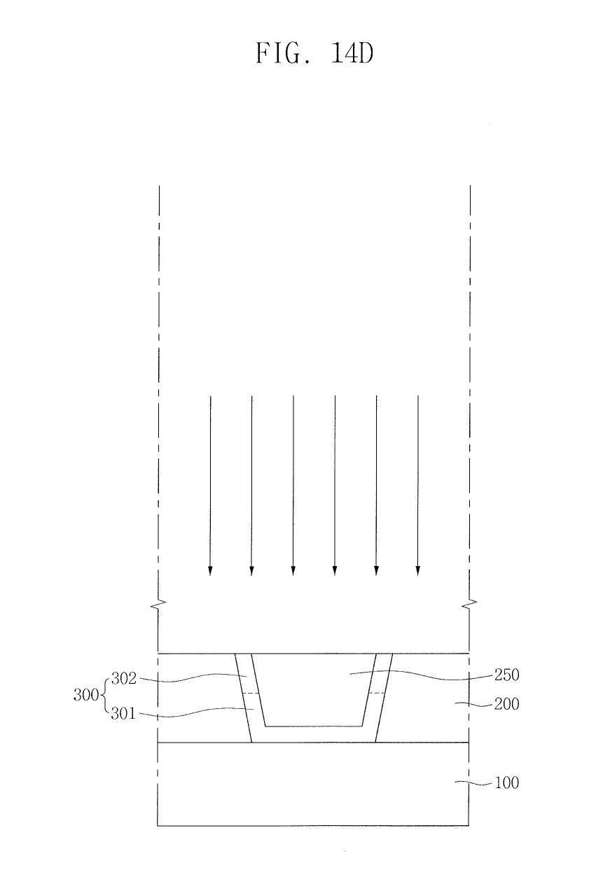

FIG. 15 is a view schematically illustrating a memory module having the magnetic memory device according to the embodiment.

Referring to FIG. 15, the memory module 1000 may be a memory card. For example, the memory module 1000 may be a micro SD card. The memory module 1000 may include the magnetic memory devices of various embodiments. Accordingly, in a memory module 1000 according to the embodiment, a degree of integration and reliability may be improved.

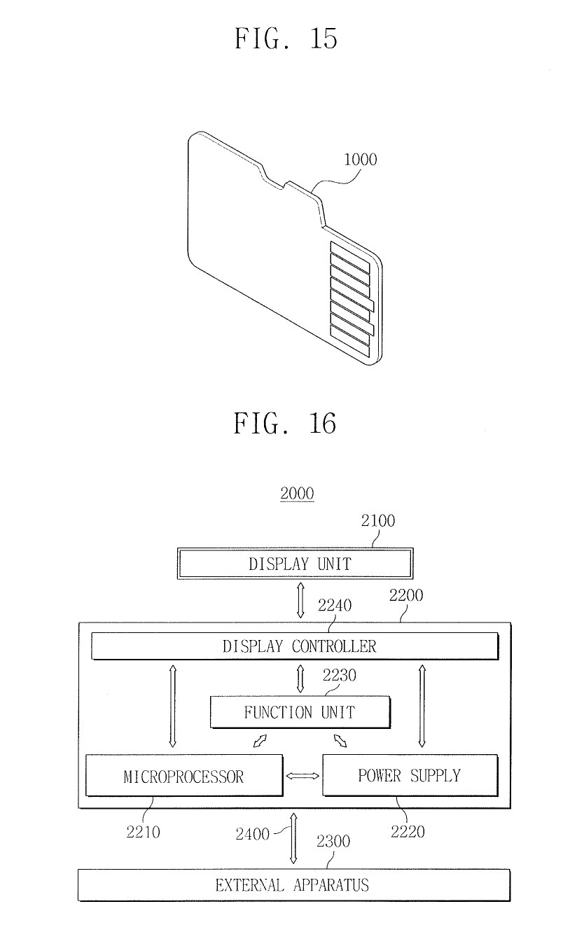

FIG. 16 is a view schematically illustrating a mobile system having the magnetic memory device according the embodiment.

FIG. 16 Referring to, the mobile system 2000 may include a display unit 2100, a body unit 2200, and an external apparatus 2300. The body unit 2200 may include a microprocessor 2210, a power supply 2220, a function unit 2230, and a display controller 2240.

The display unit 2100 may be electrically connected to the body unit 2200. The display unit 2100 may be electrically connected to the display controller 2240 of the body unit 2200. The display unit 2100 may display a processed image through the display controller 2240 of the body unit 2200.

The body unit 2200 may be a system board or a mother board including a printed circuit board (PCB). The microprocessor 2210, the power supply 2220, the function unit 2230, and the display controller 2240 may be mounted or installed on the body unit 2200.

The microprocessor 2210 may receive a voltage from the power supply 2220 and control the function unit 2230 and the display controller 2240. The power supply 2220 may receive a predetermined voltage from an external power source, divide the predetermined voltage into various voltage levels, and serve to supply the voltages to the microprocessor 2210, the function unit 2230, and the display controller 2240.

The power supply 2220 may include a power management IC (PMIC). The PMIC may effectively provide a voltage to the microprocessor 2210, the function unit 2230, and the display controller 2240.

The function unit 2230 may perform various functions of the mobile system 2000. For example, the function unit 2230 may include a dialing or various components of wireless communication functions such as an image output to the display unit 2100 or an audio output to a speaker from a communication with the external apparatus 2300. For example, the function unit 2230 may serve as a camera image processor.

The function unit 2230 may serve as a memory card controller when the mobile system 2000 includes a memory card or the like to expand a storage capacity. The function unit 2230 may serve as an interface controller when the mobile system 2000 further includes a Universal Serial Bus (USB) or the like to expand functions.

The microprocessor 2210, the power supply 2220, and the function unit 2230 may include the magnetic memory devices of various embodiments. Thus, in the mobile system 2000 according to the embodiment, a degree of integration and reliability may be improved.

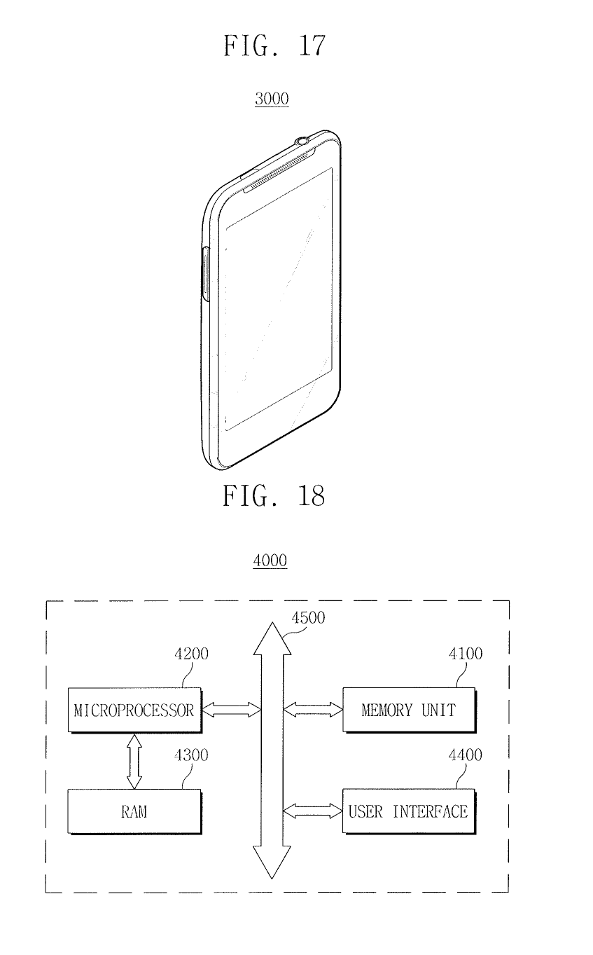

FIG. 17 is a view schematically illustrating a mobile device having the magnetic memory device according to the embodiment.

Referring to FIG. 17, for example, the mobile device 3000 may be a mobile wireless phone. For example, the mobile device 3000 may be a tablet PC. The mobile device 3000 may include the magnetic memory devices of various embodiments. Accordingly, in the mobile device 3000 according to the embodiment, reliability may be improved.

FIG. 18 is a view schematically illustrating an electronic system having the magnetic memory device according to the embodiment.

Referring to FIG. 18, the electronic system 4000 may include a memory unit 4100, a microprocessor, 4200, a random access memory (RAM) 4300, and a user interface 4400. The electronic system 4000 may be a system such as a LED lighting device, a refrigerator, an air conditioner, an industrial cutting machine, a welding machine, an automobile, a ship, an airplane, a satellite, or the like.

The memory unit 4100 may store booting codes of the microprocessor 4200, data processed by the microprocessor 4200, or external input data. The memory unit 4100 may include a controller and a memory.

The microprocessor 4200 may program and control the electronic system 4000. The RAM 4300 may be used as an operational memory of the microprocessor 4200.

The user interface 4400 may perform data communication using a bus. The user interface 4400 may be used for a data input to the electronic system 4000 or a data output from the electronic system 4000.

The memory unit 4100, the microprocessor 4200, and the RAM 4300 may include the magnetic memory devices of various embodiments. Thus, in the electronic system 4000 according to the embodiment, a degree of integration and reliability may be improved.

According to embodiments, a magnetic memory device and a method of forming the same may provide a magnetic tunnel junction pattern without being influenced by a contact plug. According to the embodiments, the magnetic memory device and the method of forming the same may not have an additional insertion layer formed to prevent an influence of a contact plug. Accordingly, according to the embodiments, the magnetic memory device and the method of forming the same may have electromagnetic characteristics of a magnetic tunnel junction pattern improved without increasing an overall height. Thus, according to the embodiments, the magnetic memory device and the method of forming the same may have a degree of integration and reliability improved.

The foregoing is illustrative of embodiments and is not to be construed as limiting thereof. Although a few embodiments have been described, those skilled in the art will readily appreciate that many modifications are possible in embodiments without materially departing from the novel teachings and advantages. Accordingly, all such modifications are intended to be included within the scope of this inventive concept as defined in the claims. In the claims, means-plus-function clauses are intended to cover the structures described herein as performing the recited function, and not only structural equivalents but also equivalent structures. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A magnetic memory device, comprising:
a contact plug including a first crystalline region and an amorphous region disposed on the first crystalline region; and
a magnetic tunnel junction pattern disposed on the amorphous region of the contact plug.

2. The magnetic memory device of claim 1, wherein the amorphous region includes a same conductive material as the first crystalline region.

3. The magnetic memory device of claim 2, wherein an amount of the conductive material in the amorphous region is smaller than an amount of the conductive material in the first crystalline region.

4. The magnetic memory device of claim 1, wherein a vertical thickness of the amorphous region is smaller than a vertical thickness of the first crystalline region.

5. The magnetic memory device of claim 1, wherein the magnetic tunnel junction pattern includes magnetic patterns and a tunnel barrier pattern disposed between the magnetic patterns, and wherein a crystallization temperature of the magnetic patterns is lower than a crystallization temperature of the amorphous region of the contact plug.

6. The magnetic memory device of claim 1, further comprising:
a lower interlayer insulating layer surrounding the contact plug,
wherein an upper surface of the amorphous region of the contact plug is coplanar with an upper surface of the lower interlayer insulating layer.

7. A magnetic memory device, comprising:
a contact plug including a first crystalline region and a second crystalline region having a same conductive material as the first crystalline region; and
a magnetic tunnel junction pattern disposed on the second crystalline region of the contact plug,
wherein the second crystalline region has a different crystalline structure from the first crystalline region.

8. The magnetic memory device of claim 7, wherein the second crystalline region has a same composition ratio as the first crystalline region.

9. The magnetic memory device of claim 7, wherein the contact plug further comprises an amorphous region disposed between the first crystalline region and the second crystalline region.

10. The magnetic memory device of claim 9, wherein the amorphous region includes a same conductive material as the second crystalline region.

11. The magnetic memory device of claim 7, wherein the contact plug further comprises a third crystalline region having a different conductive material from the first crystalline region,
wherein the first crystalline region is disposed between the second crystalline region and the third crystalline region.

12. The magnetic memory device of claim 11, wherein the first crystalline region has a same crystalline structure as the third crystalline region.

13. The magnetic memory device of claim 11, wherein a vertical thickness of the third crystalline region is greater than a vertical thickness of the first crystalline region.

14. The magnetic memory device of claim 7, wherein a horizontal width of an upper surface of the second crystalline region is different from a horizontal width of a lower surface of the magnetic tunnel junction pattern.

15. The magnetic memory device of claim 7, wherein the magnetic tunnel junction pattern includes a seed pattern in direct contact with the second crystalline region of the contact plug, and wherein the seed pattern has a same crystalline structure as the second crystalline region of the contact plug.

16. A magnetic memory device, comprising:
a lower interlayer insulating layer including a via hole;
a contact plug disposed in the via hole of the lower interlayer insulating layer; and
a magnetic tunnel junction pattern disposed on the contact plug,
wherein the contact plug includes an amorphous region disposed near the magnetic tunnel junction pattern.

17. The magnetic memory device of claim 16, wherein the amorphous region of the contact plug directly contacts the magnetic tunnel junction pattern.

18. The magnetic memory device of claim 16, further comprising:
a core pattern disposed on the contact plug,
wherein an upper surface of the core pattern is coplanar with an upper surface of the contact plug.

19. The magnetic memory device of claim 18, wherein a level of a lower surface of the core pattern is lower than a lowest level of the amorphous region of the contact plug.

20. The magnetic memory device of claim 18, wherein the core pattern includes silicon oxide.
